(19) United States
(12) Patent Application Publication
(10) Pub. No.: US 2012/0146053 A1
(43) Pub. Date: Jun. 14, 2012

(54) SEMICONDUCTOR DEVICE AND METHOD OF MANUFACTURING THE SAME

(76) Inventors: Masumi SAITOH, Kanagawa (JP); Toshinori Numata, Kanagawa (JP); Yukio Nakabayashi, Kanagawa (JP); Kensuke Ota, Kanagawa (JP)

(21) Appl. No.: 13/237,697

(22) Filed: Sep. 20, 2011

(30) Foreign Application Priority Data
Dec. 8, 2010 (JP) 2010-273271

(51) Int. Cl. H01L 29/161; H01L 21/336; H01L 29/78

(52) U.S. Cl. 257/77; 257/347; 438/299; 438/288; 257/E29.084; 257/E29.255; 257/E21.423

(57) ABSTRACT

A semiconductor device according to an embodiment includes a semiconductor substrate, a gate insulating film formed on the semiconductor substrate, a gate electrode formed on the gate insulating film, first gate sidewalls formed on both sides of the gate electrode, and a source/drain semiconductor layer formed on the semiconductor substrate to sandwich the first gate sidewalls with the gate electrode. Further, second gate sidewalls are provided on the first gate sidewalls and the source/drain semiconductor layer at both sides of the gate electrode, wherein the boundary of each of the second gate sidewalls with each of the first gate sidewalls is terminated at the side surface of the gate electrode, and each of the second gate sidewalls has a smaller Young's modulus and a lower dielectric constant than each of the first gate sidewalls.

### CROSS-REFERENCE TO RELATED APPLICATION

This application is based upon and claims the benefit of priority from Japanese Patent Application No. 2010-273271, filed on Dec. 8, 2010, the entire contents of which are incorporated herein by reference.

### FIELD

Embodiments described herein relate generally to a semiconductor device and a method of manufacturing the same.

### BACKGROUND

The performance of MISFETs are still continued to be improved by reducing gate lengths. However, when a gate length becomes 50 nm or less, the resistance of a channel region under the gate decreases but the parasitic resistance in a source/drain region formed by a shallow impurity region is constant or increases. Accordingly, a ratio of a parasitic resistance with respect to a total transistor resistance increases, which degrades the performance of the transistor.

There is a method for increasing the volume of the source/drain region by selective epitaxial growth of silicon in the source/drain region in order to reduce the parasitic resistance in the source/drain region.

Selective epitaxial growth of silicon in the source/drain region realizes strong short-channel effect immunity. Therefore, this is considered to be indispensable in three-dimensional transistors such as a FinFET and a nanowire transistor, required in the era of further scaling down. This is because, in the three-dimensional transistor, not only the channel region but also the source/drain region is in a thin line form, which increases the parasitic resistance of the source/drain region.

### BRIEF DESCRIPTION OF THE DRAWINGS

FIG. 1 is a cross-sectional schematic diagram illustrating a semiconductor device according to a first embodiment;

FIG. 2 is a top surface schematic diagram illustrating the semiconductor device according to the first embodiment;

FIG. 3 is a cross-sectional schematic diagram illustrating the semiconductor device according to the first embodiment;

FIG. 4 is a cross-sectional schematic diagram illustrating the semiconductor device according to the first embodiment;

FIGS. 5 to 16 are schematic diagrams illustrating steps of a method of manufacturing the semiconductor device according to the first embodiment;

FIG. 17 is a cross-sectional TEM picture of the first embodiment;

FIG. 18 is a graph illustrating a measurement result of mobility of a nanowire transistor according to the first embodiment;

FIGS. 19A, 19B, and 19C are figures illustrating cross-sectional structures of transistors assumed in a device simulation according to the first embodiment;

FIG. 20 is a figure illustrating a result obtained by calculating a parasitic capacitance per unit gate width according to the first embodiment;

FIG. 21 is an explanatory diagram illustrating a distance between a first sidewall and a second sidewall of the first embodiment;

FIGS. 22A and 22B are cross-sectional schematic diagrams illustrating a semiconductor device according to a second embodiment;

FIGS. 23A, 23B, and 23C are cross-sectional schematic diagrams illustrating a semiconductor device according to a third embodiment;

FIG. 24 is a cross-sectional schematic diagram illustrating a semiconductor device according to a fourth embodiment;

FIGS. 25 to 28 are schematic diagrams illustrating steps of a method of manufacturing the semiconductor device according to the fourth embodiment;

FIGS. 29A and 29B are cross-sectional schematic diagrams illustrating a semiconductor device according to a fifth embodiment;

FIG. 30 is a top surface schematic diagram illustrating a semiconductor device according to a sixth embodiment;

FIG. 31 is a cross-sectional schematic diagram illustrating the semiconductor device according to the sixth embodiment;

FIG. 32 is a cross-sectional schematic diagram illustrating the semiconductor device according to the sixth embodiment; and

FIGS. 33 to 39 are schematic diagrams illustrating steps of a method of manufacturing the semiconductor device according to the sixth embodiment.

### DETAILED DESCRIPTION

A semiconductor device according to an embodiment includes a semiconductor substrate, a gate insulating film formed on the semiconductor substrate, a gate electrode formed on the gate insulating film, first gate sidewalls formed on both sides of the gate electrode, and a source/drain semiconductor layer formed on the semiconductor substrate. The first gate sidewalls being interposed between the source/drain semiconductor layer and the gate electrode. Further, second gate sidewalls are provided on the first gate sidewalls and the source/drain semiconductor layer at both sides of the gate electrode, wherein the boundary of each of the second gate sidewalls with each of the first gate sidewalls is terminated at the side surface of the gate electrode, and each of the second gate sidewalls has a smaller Young's modulus and a lower dielectric constant than each of the first gate sidewalls.

Embodiments will be hereinafter explained with reference to the drawings.

In this specification, notations (100) plane and (110) plane are used to representatively denote {100} plane and {110} plane. Further, notations <100> direction and <110> direction are used to represent directions equivalent to [100] direction and [110] direction in terms of crystallography.

In this specification, silicon germanium and silicon carbon are not the concept limited to a crystal in which silicon and germanium are regularly arranged and a crystal in which silicon and carbon are regularly arranged, but the silicon germanium and the silicon carbon also mean crystals in which germanium and carbon are randomly contained in silicon.

### First Embodiment

The semiconductor device according to the present embodiment includes a semiconductor substrate, a gate insulating film formed on the semiconductor substrate, a gate electrode formed on the gate insulating film, first gate sidewalls formed on both sides of the gate electrode, a source/drain semiconductor layer formed on the semiconductor substrate to sandwich the first gate sidewalls with the gate electrode, and second gate sidewalls provided on the first gate sidewalls and the source/drain semiconductor layer at both sides of the gate electrode, wherein the boundary of each of the second gate sidewalls with each of the first gate sidewall is terminated at the side surface of the gate electrode, and each of the second gate sidewalls has a smaller Young's modulus and a lower dielectric constant than each of the first gate sidewalls.

The semiconductor substrate has a substrate semiconductor layer including a narrow portion. Further, the gate insulating film is formed on the side surfaces and the top surface of the narrow portion.

The semiconductor device according to the present embodiment is a so-called nanowire transistor. Hereinafter, in particular, an n-type nanowire transistor will be explained.

The mobility of this nanowire transistor is improved by strain given by the first gate sidewall to the channel region. On the other hand, the second sidewall having low dielectric constant reduces the parasitic capacitance.

In addition, a stable and reproducible method of manufacturing the gate sidewalls can be employed. Therefore, this reduces uneveness in the process, and achieves less-varying transistor characteristics.

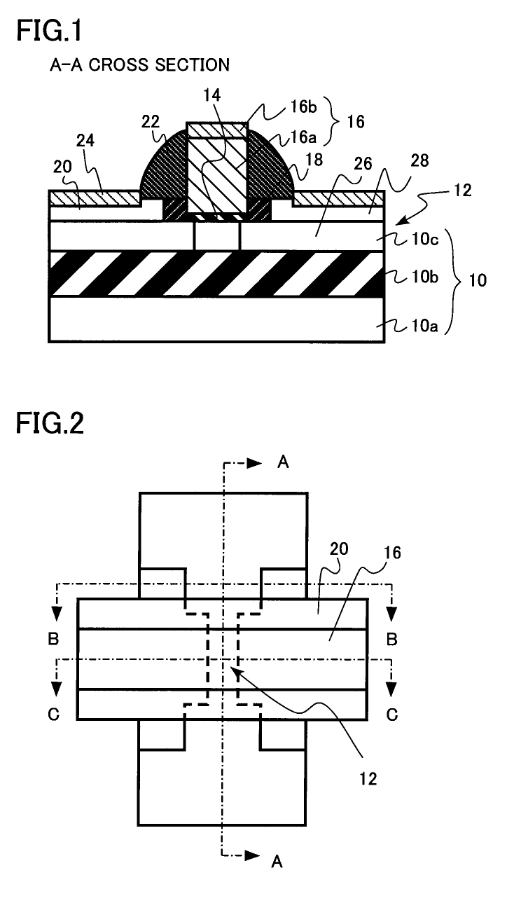

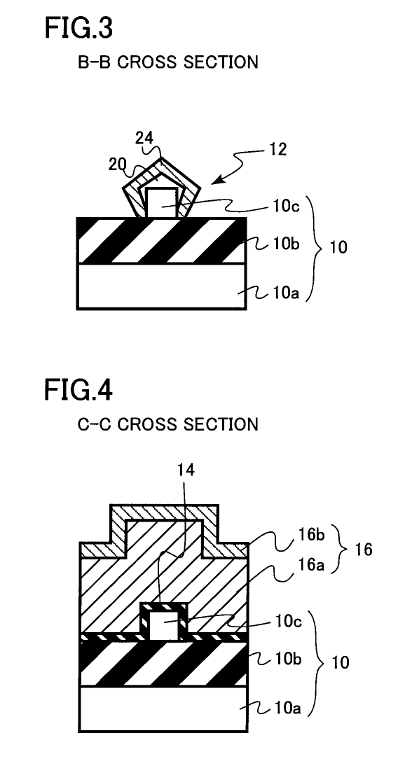

FIG. 1 is a cross-sectional schematic diagram illustrating a semiconductor device according to the present embodiment. FIG. 2 is a top surface schematic diagram according to the present embodiment. FIG. 1 is a cross-sectional schematic diagram taken along cross section A-A of FIG. 2. FIG. 3 is a cross-sectional schematic diagram taken along cross section B-B of FIG. 2. FIG. 4 is a cross-sectional schematic diagram taken along cross section C-C of FIG. 2.

The nanowire transistor according to the present embodiment is formed on a semiconductor substrate 10. The semiconductor substrate 10 is, for example, an SOI (Silicon On Insulator) substrate.

The semiconductor substrate 10 includes, for example, a (100) plane silicon substrate 10a, an buried oxide film 10b formed on the silicon substrate, and an SOI layer 10c including a narrow portion 12 formed on the buried oxide film 10b. The narrow portion 12 corresponds to a so-called nanowire or a silicon nanowire. Hereinafter, this is referred to as a silicon nanowire. The SOI layer 10c corresponds to a substrate semiconductor layer. FIG. 2 shows only one narrow portion 12. However, a plurality of narrow portions 12 may be provided in parallel on the substrate semiconductor layer.

A gate insulating film 14 is formed on side surfaces and a top surface of the narrow portion 12. The gate insulating film 14 is, for example, a silicon oxide film. The gate insulating film 14 is not limited to the silicon oxide film. It may be a high dielectric constant (high-k film) such as silicon oxynitride film, hafnium oxide film, and zirconium oxide film, or a stacked film including a silicon oxide film and high dielectric constant film.

A gate electrode 16 is formed on the gate insulating film 14. In the present embodiment, the gate electrode 16 is formed with a polysilicon layer 16a and a metal silicide layer 16b. The metal silicide layer 16b is, for example, nickel silicide. The metal silicide layer 16b is not limited to the nickel silicide. It may be a metal silicide such as platinum silicide, nickel platinum silicide, and cobalt silicide. The gate electrode 16 may be formed with, for example, a metal-semiconductor compound single film such as a polysilicon single film and metal silicide, a metal film such as titanium nitride (TiN), tungsten (W), and tantalum carbide (TaC), a stacked film including a metal-semiconductor compound film other than the metal silicide and a semiconductor such as a polysilicon film, or a stacked film including a metal film and a semiconductor such as a polysilicon film.

On both sides of the gate electrode 16, first gate sidewalls 18 are formed to sandwich the gate electrode 16. The first gate sidewall 18 is, for example, a silicon nitride film.

Source/drain semiconductor layers 20 are formed on the semiconductor substrate 10 at both sides of the gate electrode 16. The first gate sidewall 18 is sandwiched or interposed between the source/drain semiconductor layer 20 and the gate electrode 16. The source/drain semiconductor layer 20 is, for example, a silicon layer formed by selective epitaxial growth.

Second gate sidewalls 22 are formed at both sides of the gate electrode 16 to sandwich the gate electrode 16. The second gate sidewall 22 is formed on the first gate sidewall 18 and the source/drain semiconductor layer 20 so as to extend over the first gate sidewall 18 and the source/drain semiconductor layer 20.

One end of a boundary between the first gate sidewall 18 and the second gate sidewall 22 is terminated at a side surface of the gate electrode 16. In other words, one end of the second gate sidewall 22 is in contact with the side surface of the gate electrode 16.

The second gate sidewall 22 has a Young's modulus less than the first gate sidewall 18 and a dielectric constant lower than the first gate sidewall 18. When the first gate sidewall 18 is a silicon nitride film, the second gate sidewall 22, for example, a silicon oxide film having a Young's modulus less than the silicon nitride film and a dielectric constant lower than the silicon nitride film. For example, the first gate sidewall 18 may be a silicon oxynitride film, and the second gate sidewall 22 may be a silicon oxide film.

The first sidewall insulating film 18 may be a so-called high-k film such as a tantalum oxide film, a hafnium oxide film, and a zirconium oxide film having a higher dielectric constant than the silicon oxide film. On the other hand, the second sidewall insulating film 22 may be a so-called low-k film such fluorine-doped silicon oxide and carbon-doped silicon oxide having a lower dielectric constant than the silicon oxide film.

Metal silicide layers 24 are formed on the source/drain semiconductor layer 20 at both sides of the second gate sidewall 22. The metal silicide layer 24 is, for example, nickel silicide. The metal silicide layer 24 is not limited to the nickel silicide. It may be metal silicide such as platinum silicide, nickel platinum silicide, and cobalt silicide.

Extension impurity regions 26 are formed in the SOI layer 10c at both sides of the gate electrode 16. A source/drain impurity region 28 is formed in the source/drain semiconductor layer 20 at both sides of the gate electrode 16. The extension impurity region 26 and the source/drain impurity region 28 function as a source/drain region.

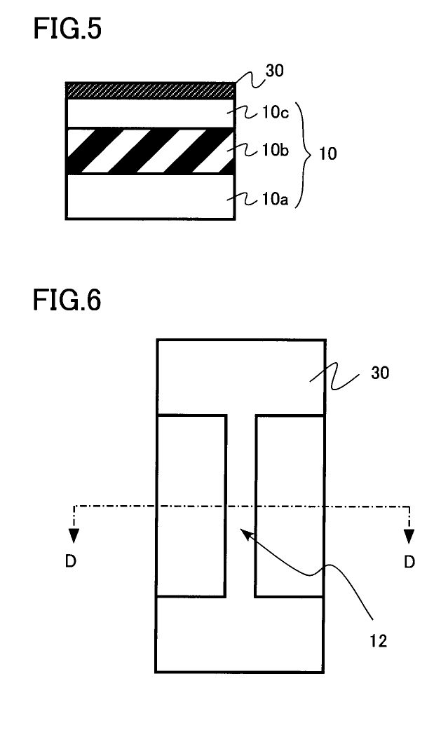

Hereinafter, a method of manufacturing the semiconductor device according to the present embodiment will be explained. FIGS. 5 to 16 are schematic diagrams illustrating steps of the method of manufacturing the semiconductor device according to the present embodiment. FIGS. 5, 7, 8, 11, 13, 15, and 16 are cross-sectional schematic diagrams. FIGS. 6, 9, 10, 12, and 14 are top surface schematic diagrams.

The method of manufacturing the semiconductor device according to the present embodiment includes forming a gate insulating film on a semiconductor substrate, forming a gate electrode on the gate insulating film, forming first gate sidewalls at both sides of the gate electrode, forming source/drain semiconductor layers on the semiconductor substrate at both sides of the gate electrode by selective growth, performing thermal processing, performing wet etching to remove portions of the first gate sidewalls, and forming second gate sidewalls on the first gate sidewall and the source/drain semiconductor layer at both sides of the gate electrode, wherein the second gate sidewall has a smaller Young's modulus and a lower dielectric constant than the first gate sidewall.

First, as shown in FIG. 5, for example, the semiconductor substrate 10 is prepared in which the buried oxide film 10b and the SOI layer 10c are formed on the silicon substrate 10a of (100) plane. Then, a hard mask layer 30 is formed on an SOI layer (substrate semiconductor layer) 10c at the upper portion of the semiconductor substrate 10. The thickness of the SOI layer 10c is, for example, about 3 to 40 nm. The hard mask layer 30 is, for example, a silicon nitride film.

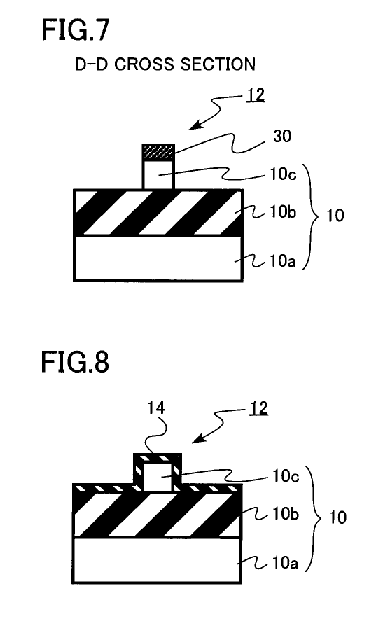

Subsequently, as shown in FIG. 6 showing the top surface schematic diagram and FIG. 7 showing the cross-sectional schematic diagram taken along cross section D-D of FIG. 6, the hard mask layer 30 is patterned. Thereafter, using the hard mask layer 30 as a mask, the SOI layer 10c is etched, and the narrow portion 12 being narrower in some portion in the gate widthwise direction is formed in the SOI layer 10c. The narrow portion 12 is a so-called silicon nanowire. The width of the silicon nanowire 12 is, for example, about 3 to 20 nm.

When the hard mask layer 30 is patterned, the gate lengthwise direction and the narrow direction of the narrow portion 12 are both formed in <110> direction, so that the side surfaces of the etched silicon nanowire are in (110) plane. When the gate lengthwise direction and the narrow direction of the narrow portion 12 are both formed in <100> direction, the side surfaces of the etched silicon nanowire are in (100) plane.

Subsequently, as shown in FIG. 8 showing the cross-sectional schematic diagram in the gate widthwise direction, the hard mask layer 30 is removed, and thereafter the gate insulating film 14 is formed on the side surfaces and the top surface of the silicon nanowire 12. The gate insulating film 14 is, for example, a silicon oxide film. The gate insulating film 14 is not limited to the silicon oxide film. It may be a high dielectric constant film (high-k film) such as silicon oxynitride film, hafnium oxide film, and zirconium oxide film, or a stacked film including a silicon oxide film and a high dielectric constant film.

Subsequently, the polysilicon layer 16a of the gate electrode is formed on the gate insulating film 14, and further, for example, a hard mask nitride film 32 of, for example, a silicon nitride film, is formed on the polysilicon layer 16a. Then, the hard mask nitride film 32 is patterned. The ultimately formed gate electrode may be, for example, a metal-semiconductor compound single film such as a polysilicon single film and metal silicide, a metal film such as TiN, W, and TaC, a stacked film including a metal-semiconductor compound film and a semiconductor such as a polysilicon film, or a stacked film including a metal film and a semiconductor such as a polysilicon film.

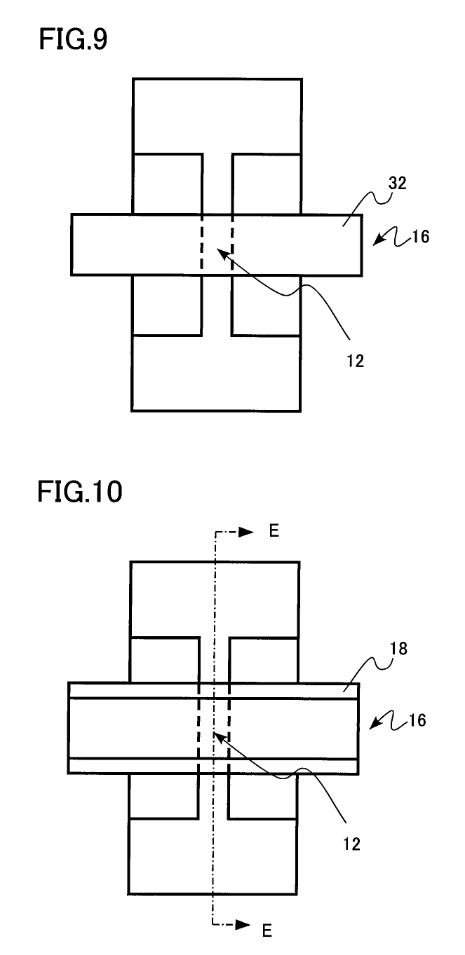

Subsequently, using the hard mask nitride film 32 as a mask, the polysilicon layer 16a and the gate insulating film 14 are patterned. Then, as shown in FIG. 9 showing the top surface schematic diagram, the polysilicon layer 16a of the gate electrode and the gate insulating film 14 are left only on some portion of the silicon nanowire 12.

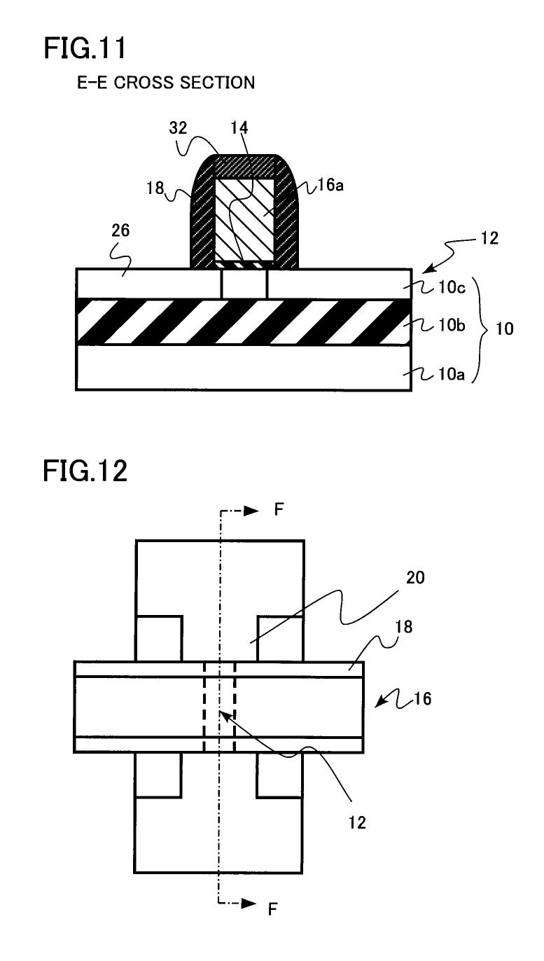

Subsequently, after, for example, the silicon nitride film is deposited on the entire surface, the first gate sidewalls 18 of the silicon nitride film are formed on both sides of the polysilicon layer 16a of the gate electrode by dry etching, as shown in FIG. 10 showing the top surface schematic diagram and FIG. 11 showing the cross-sectional schematic diagram showing cross section E-E of FIG. 10. The thickness of the first gate sidewall 18 in the gate lengthwise direction is preferably 5 nm or more in order to reduce the parasitic capacitance, and is preferably 30 nm or less since it is necessary to reduce the parasitic resistance by reducing the distance between the gate electrode 16 and an epitaxial layer formed later.

Subsequently, by performing ion implantation, the extension impurity region 26 is formed in the SOI layer 10c which is exposed and whose upper portion is not formed with the polysilicon layer 16a of the gate electrode or the first gate sidewall 18.

The ion implantation for forming the extension impurity region 26 is preferably performed with a relatively low acceleration voltage. For example, ion implantation of arsenic (As) is performed at about 1 to 4 keV.

After ion implantation, the crystallinity of the silicon nanowire 12 is recovered by performing annealing process under a nitrogen atmosphere. The annealing temperature is preferably 800° C. or more since it is necessary to perform sufficient activation and re-crystallization, and is preferably 1100° C. or less in order to prevent excessive impurity diffusion. It should be noted that this ion implantation and annealing process may be omitted.

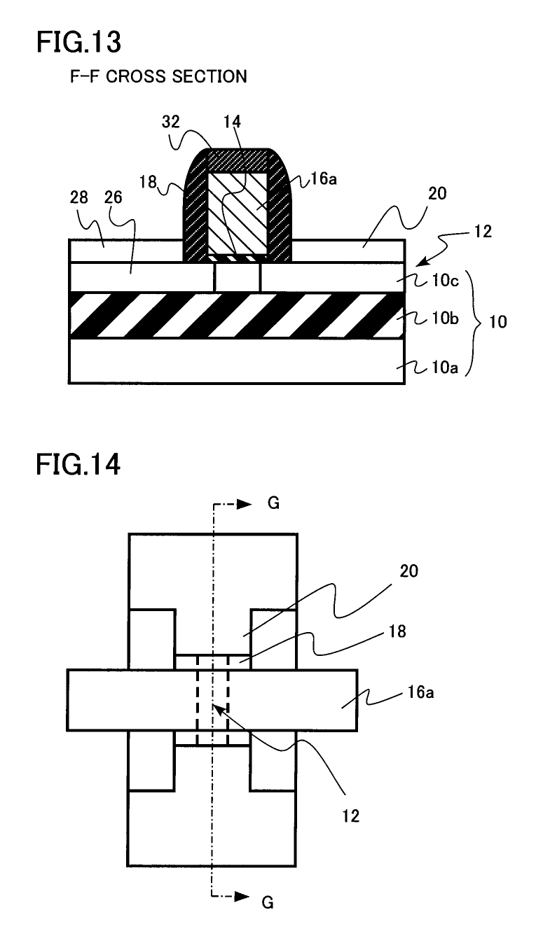

Subsequently, as shown in FIG. 12 showing the top surface schematic diagram and FIG. 13 showing the cross-sectional schematic diagram taken along cross section F-F of FIG. 12, the epitaxial silicon layers serving as the source/drain semiconductor layers 20 are formed on the exposed portions of the SOI layers 10c by selective epitaxial growth. In this case, the process for selectively forming the epitaxial films on the exposed portions of the SOI layers 10c is, for example, performing diluted hydrofluoric acid treatment and hydrogen baking for removing natural oxide films on the surfaces of the SOI layers 10c and thereafter growing the epitaxial silicon layer using hydrochloric acid as etching gas and dichlorosilane gas as a deposition gas under an atmosphere of hydrogen carrier gas.

The thickness of the epitaxial silicon layer 20 is preferably 10 nm or more in order to reduce the parasitic resistance, and is preferably 50 nm or less in order to reduce the parasitic capacitance between the gate electrode 16 and the source/drain semiconductor layer 22 and reduce the process time.

Subsequently, the source/drain impurity region 28 is formed by performing ion implantation into the epitaxial silicon layer 20. The types of impurity injected by ion implantation may be phosphorus (P) or arsenic (As).

The source/drain impurity region 28 formed here and the extension impurity region 26 formed work as the source/drain region. The impurity concentration of the source/drain impurity region 28 is preferably 1×10¹⁹ cm⁻³ or more in order to reduce the parasitic resistance.

Subsequently, thermal processing, i.e., annealing, is performed to activate the impurity in the source/drain impurity region 28. During the annealing process, thermal expansion of the first gate sidewall 18, i.e., the silicon nitride film, is suppressed by the gate electrode 16 and the source/drain semiconductor layer 20, i.e., the epitaxial silicon layer, at both sides. Accordingly, this increases the density of the region of the first gate sidewall 18 sandwiched by the gate electrode 16 and the source/drain semiconductor layer 20, i.e., the region under the top surface of the source/drain semiconductor layer 20. The annealing temperature is preferably 800° C. or more for the need of sufficient activation, and is preferably 1100° C. or less in order to prevent excessive impurity diffusion.

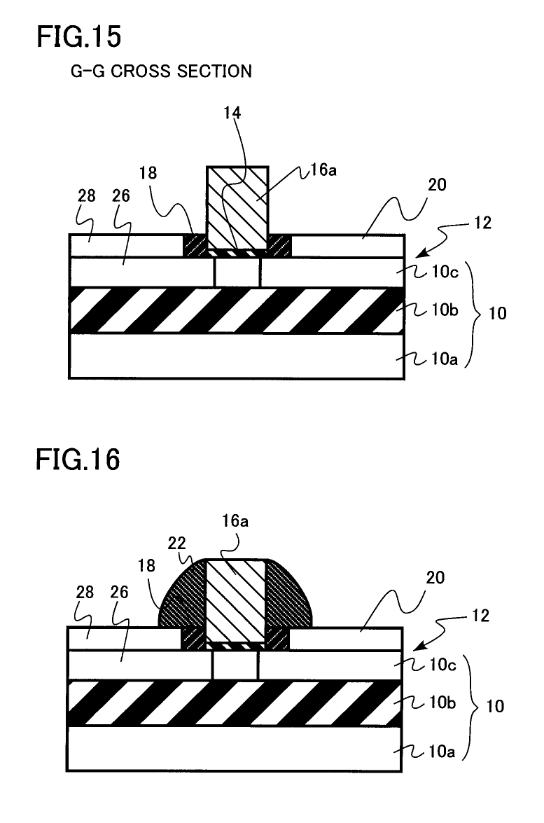

Subsequently, as shown in FIG. 14 showing the top surface schematic diagram and FIG. 15 showing the cross-sectional schematic diagram taken along surface G-G of FIG. 14, wet etching is performed with hot phosphoric acid, so as to remove portions of the first gate sidewalls 18 and the hard mask nitride film 32 on the polysilicon layer 16a of the gate electrode serving as the silicon nitride film. The removed portion of the first gate sidewall 18 is an upper portion of the first gate sidewall 18, i.e., the region above the top surface of the source/drain semiconductor layer 20.

During this wet etching, the density of the region below the top surface of the source/drain semiconductor layer 20 of the first gate sidewall 18 is increased during the above annealing process. Therefore, the etching rate with the hot phosphoric acid is greatly reduced, and it remains without being removed in a self-aligning manner. In particular, the etching rate of the silicon nitride film with the hot phosphoric acid is significantly reduced, and therefore, the silicon nitride film is preferable as a material of the first gate sidewall 18.

Subsequently, after, for example, the silicon oxide film is deposited on the entire surface, the second gate sidewalls 22 are formed on the first gate sidewall 18 and the source/drain semiconductor layer 20 at both sides of the polysilicon layer 16a of the gate electrode by dry etching so as to sandwich the polysilicon layer 16a of the gate electrode, as shown in the schematic cross-sectional diagram of FIG. 16.

The material of the second gate sidewall 22 formed here is not particularly limited as long as it is a material having a smaller Young's modulus and a lower dielectric constant than the material of the first gate sidewall 18. For example, it is preferably a silicon oxide film such as a TEOS (tetraethoxysilane) film.

Examples of combinations in which the material of the second gate sidewall 22 has a smaller Young's modulus and a lower dielectric constant than the material of the first gate sidewall 18 include, for example, a combination including the first gate sidewall 18 made of a silicon nitride film and the second gate sidewall 22 made of a silicon oxide film, a combination including the first gate sidewall 18 made of a silicon nitride film and the second side wall 22 made of a silicon oxynitride film, and a combination including the first gate sidewall 18 made of a silicon oxynitride film and the second side wall 22 made of a silicon oxide film.

After forming the second gate sidewall 22, the impurity concentration of the source/drain region may be enhanced by performing ion implantation and activation annealing process.

Thereafter, using so-called salicide process, the metal silicide layer 16b on the polysilicon layer 16a on the gate electrode and the metal silicide layer 24 on the source/drain semiconductor layer 20 are formed. As a result of the above process, the semiconductor device according to the present embodiment as shown in FIG. 1 is formed.

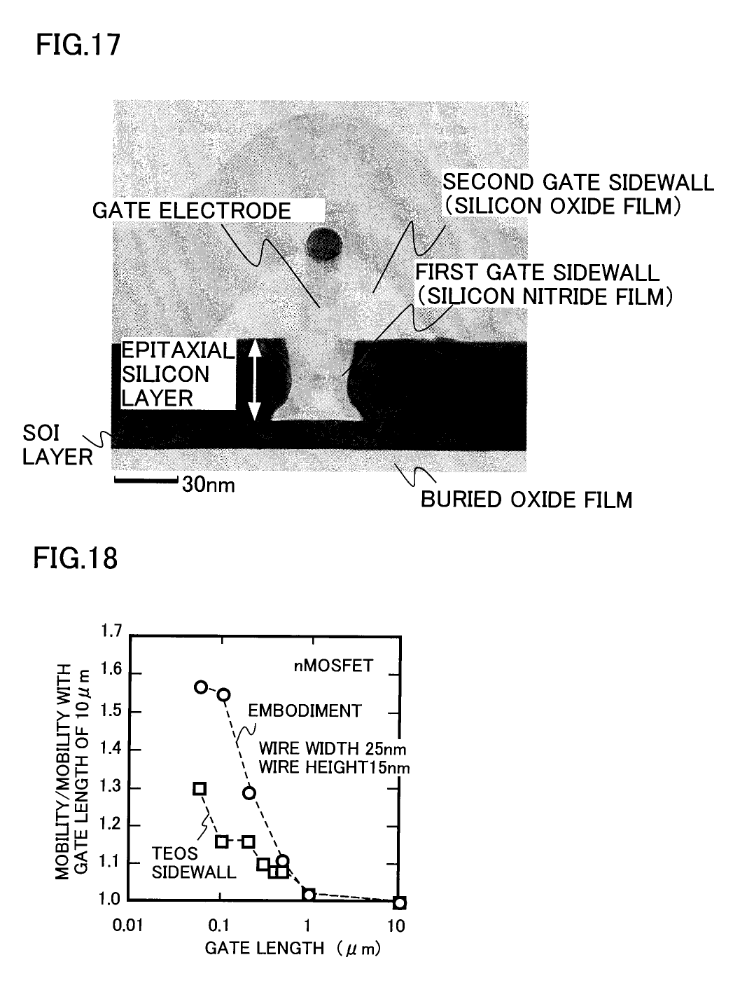

FIG. 17 is a cross-sectional TEM picture illustrating a nanowire transistor in the gate lengthwise direction that is generated by actually performing the above process. Since the density of the silicon nitride film in the region under the top surface of the epitaxial silicon layer is increased due to the annealing process, it remains without being removed during the wet etching with the hot phosphoric acid, so that the first gate sidewall 18 is formed.

In the nanowire transistor according to the present embodiment, the silicon nanowire has a structure in which a width (length in gate widthwise direction) is about 3 to 20 nm and a height is about 3 to 40 nm. In this structure, the gate strongly controls the electric field of the channel region from three directions, i.e., the top surface and right/left side surfaces of the channel region in the silicon nanowire. Therefore, the nanowire transistor according to the present embodiment can operate as an extremely short-channel transistor having a gate length of 30 nm or less. It should be noted that the side surfaces of the silicon nanowire are in (110) plane or (100) plane.

When the nanowire transistor according to the present embodiment has, for example, a source/drain semiconductor layer 20 having a thickness of 10 to 50 nm, the size of the cross-sectional area of the source/drain region increases. Therefore, the parasitic resistance is greatly reduced, and the ON current of the transistor increases.

In the semiconductor device according to the present embodiment, the first gate sidewall 18 having a large Young's modulus is formed between the polysilicon layer 16a of the gate electrode of the n-type transistor and the source/drain semiconductor layer 20 formed by, for example, epitaxial growth. The first gate sidewall 18 having the large Young's modulus pressurizes the polysilicon layer 16a, so that the compressive strain occurs in a direction perpendicular to the side surface and the top surface of the silicon nanowire and the tensile strain occurs in the gate lengthwise direction of the channel region.

In the method of manufacturing the semiconductor device according to the present embodiment, the thermal expansion of the first gate sidewall 18 is suppressed by the gate electrode 16 and the source/drain semiconductor layer 20 at both sides during the annealing, i.e., thermal processing. As a result, the first gate sidewall 18 pressurizes the polysilicon layer 16a, so that the compressive strain occurs in a direction perpendicular to the side surface and the top surface of the silicon nanowire and the tensile strain occurs in the gate lengthwise direction of the channel region.

As described above, in the channel region of the nanowire transistor, a large tensile strain occurs in the gate lengthwise direction of the nanowire transistor. When the nanowire transistor is an n-type transistor, the mobility of the nanowire transistor improves due to such tensile strain in the gate lengthwise direction. Therefore, the mobility of the n-type transistor increases, and as a result, ON current performance improves.

FIG. 18 is a figure illustrating a measurement result of gate length dependency of mobility of the n-type nanowire transistor manufactured according to the manufacturing method of the present embodiment. The nanowire is a silicon nanowire, and the width of the nanowire is 25 nm, and the height of the nanowire is 15 nm. The mobility is represented as a ratio with respect to the mobility of the gate length of 10 μm. FIG. 18 shows a result of the structure of the present embodiment in which the silicon nitride film sidewall is left only between the polysilicon gate electrode and the source/drain semiconductor layer formed by the epitaxial silicon growth. And the figure also shows a result of the entirely TEOS sidewall (SiO₂ sidewall) structure whose sidewall is formed only by TEOS, for reference.

Regardless of the type of the gate sidewall, the mobility increases as the gate length is shorter, i.e., short-channel, but the increasing rate is higher in the structure of the present embodiment. This is considered to be affected by the strain of the silicon nitride film sidewall. In this manner, the structure of the present embodiment improves the mobility of the transistor, and as a result, the current performance improves.

With scaling down of a device, the distance between the two transistors, i.e., a so-called gate pitch, is reduced in order to reduce the size of the circuit. In the structure of the present embodiment, strain occurs by the sidewall disposed very close to the gate, and accordingly, large strain effect can be obtained even in a case of a short gate pitch.

In addition, when silicon nitride film stress liner technique which is generally used as strain introduction technique to a channel of a transistor, i.e., a method for depositing a silicon nitride film having stress on the entire upper portion of the gate sidewall and the gate electrode, is introduced to the present embodiment, the induced amount of strain can be further increased.

In the above explanation, silicon is mainly explained as an example of an epitaxial semiconductor film forming the source/drain semiconductor layer 20. Alternatively, when the epitaxial semiconductor film is, for example, silicon carbon having a lattice constant smaller than silicon, the tensile strain in the gate lengthwise direction can be increased in the channel region.

In the above explanation, the stacked layer structure including the polysilicon layer and the metal silicide layer is explained as an example of the gate electrode 16. Alternatively, even when the gate electrode 16 has a structure of a polysilicon single layer or a structure made by laminating polysilicon having a thickness of several dozens nm on a thin metal having a thickness of about 10 nm as the gate electrode, almost the same strain effects as in the stacked layer structure including the polysilicon layer and the metal silicide layer can be expected.

When a metal single layer or a stacked layer structure including different metal materials is employed as the gate electrode 16, the thermal expansion coefficient of the metal is higher than the thermal expansion coefficient of silicon and the silicon nitride film in general. Therefore, when the first gate sidewall of the silicon nitride film is sandwiched between the gate electrode and the epitaxial silicon layer and is annealed, the first gate sidewall of the silicon nitride film is compressed more strongly than the gate electrode of polysilicon, so that a higher density is considered to be achieved in the first gate sidewall of the silicon nitride film. Therefore, large strain is applied to the channel region of the nanowire existing under the metal gate electrode, and this further increases the effect of improving the mobility of the n-type nanowire transistor.

In the nanowire transistor according to the present embodiment, the second gate sidewall 22 having a lower low dielectric constant than the first gate sidewall 18 is provided on the first gate sidewalls 18. Therefore, for example, the capacitance between the gate electrode 16 and the source/drain semiconductor layer 20 and the capacitance between the gate electrode 16 and a contact plug (not shown) formed on the source/drain semiconductor layer 20 becomes less than the capacitance in a case where the second gate sidewall 22 is made of the same material as the first gate sidewall 18, and as a result, the operation speed of the transistor improves.

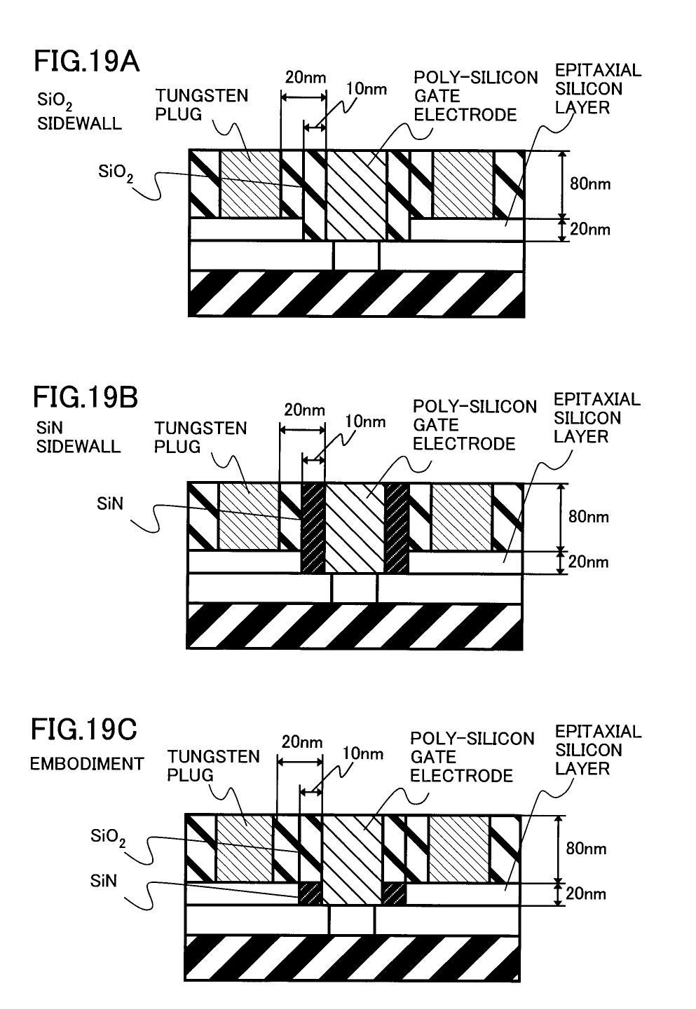

How the parasitic capacitance changes according to the type of a material of the gate sidewall was calculated using a device simulation. FIGS. 19A, 19B, and 19C are figures illustrating cross-sectional structures of transistors assumed in the device simulation. An epitaxial silicon layer of 20 nm is formed as a source/drain semiconductor layer, and the distance between a gate electrode and the epitaxial silicon layer is 10 nm. The distance between the gate electrode and a tungsten plug (metal wiring) is 20 nm. Three types of simulations are performed. In the first type, TEOS sidewalls having a thickness of 10 nm are formed on the entire surfaces at both sides of the gate electrode (SiO₂ sidewall: FIG. 19A). In the second type, silicon nitride film sidewalls having a thickness of 10 nm are formed on the entire surfaces at both sides of the gate (SiN sidewall: FIG. 19B). In the third type, silicon nitride film sidewalls are formed between the gate electrode and the epitaxial silicon layers, and TEOS sidewalls having a thickness of 10 nm are formed in the regions above the epitaxial silicon layers at both sides of the gate electrode (embodiment: FIG. 19C). It should be noted that the regions other than the above sidewalls between the gate electrode and the tungsten plugs (metal wirings) are assumed to be SiO₂.

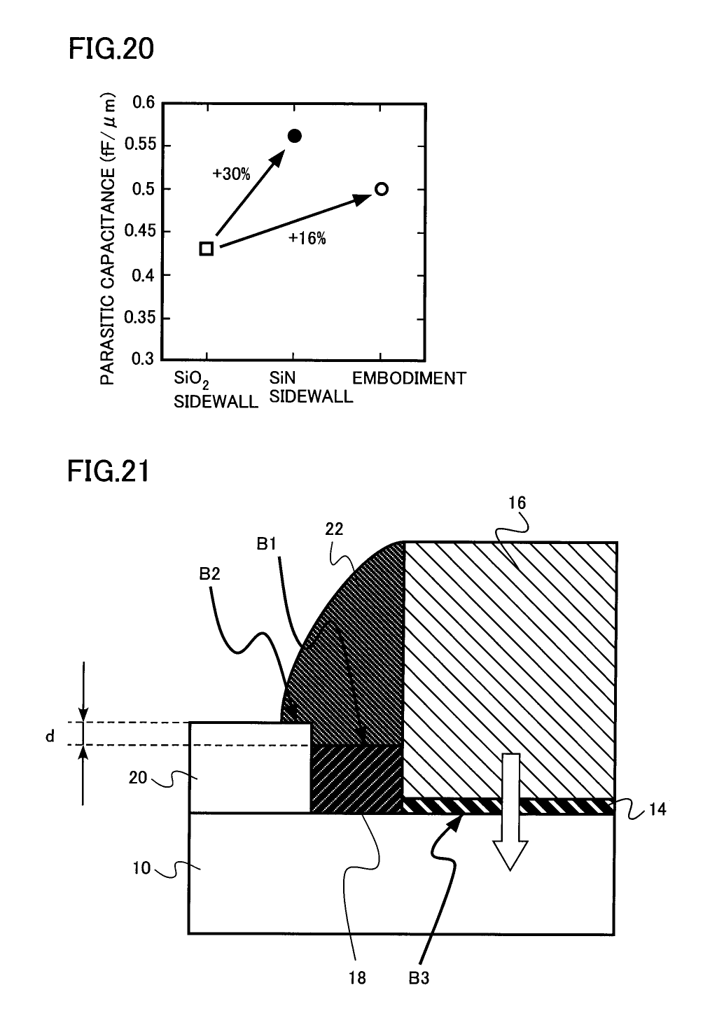

FIG. 20 is a figure illustrating a result obtained by calculating a parasitic capacitance per unit gate width. The silicon nitride film has a higher dielectric constant than the TEOS. Accordingly, in the case of the SiN sidewall, the capacitance increases by 30% as compared with the SiO₂ sidewall. However, in the case of the present embodiment in which the silicon nitride film sidewall is formed only between the gate electrode and the epitaxial silicon layer, the capacitance increases by only 15%. Therefore, in the present embodiment, the parasitic capacitance decreases as compared with the case of the SiN sidewall, and the operation speed of the transistor improves.

FIG. 21 is an explanatory diagram illustrating a distance between a first sidewall and a second sidewall of the present embodiment.

In the present embodiment, a first boundary surface B1 between the first gate sidewall 18 and the second gate sidewall 22 is at the side of the semiconductor substrate 10 (lower side in FIG. 21) with respect to a second boundary surface B2 between the source/drain semiconductor layer 20 and the second gate sidewall 22, and the distance between the first boundary surface B1 and the second boundary surface B2 is preferably 10 nm or less in a normal line direction of a boundary surface B3 between the gate insulating film 14 and the semiconductor substrate 10. The entire first boundary surface B1 is preferably at the side of the semiconductor substrate 10 with respect to the second boundary surface B2. However, for example, a portion of the first boundary surface B1 in proximity to the gate electrode 16 may be at the side opposite to the semiconductor substrate 10 with respect to the second boundary surface B2 (upper side in FIG. 21).

FIG. 21 shows a cross section substantially perpendicular to the first boundary surface B1 and the second boundary surface B2. For example, “the distance between the first boundary surface and the second boundary surface in the normal line direction of the boundary surface between the gate insulating film and the semiconductor substrate” is a distance represented by a distance d in FIG. 21. In FIG. 21, the normal line direction of the boundary surface between the gate insulating film and the semiconductor substrate is represented by a white arrow.

When the distance between the first boundary surface B1 and the second boundary surface B2 is not constant, the maximum value of the distance evaluated in the cross section is preferably 10 nm or less.

When the distance becomes more than 10 nm, the volume of the first sidewall 18 becomes insufficient, and the tensile strain in the gate lengthwise direction of the nanowire transistor is reduced. Therefore, sufficient mobility improvement effect may not be obtained. When the first boundary surface B1 is at the side opposite to the semiconductor substrate 10 with respect to the second boundary surface B2, i.e., at the upper side in the figure, the volume of the first sidewall 18 having a dielectric constant increases excessively. Therefore, the degradation of the performance caused by the increase of the parasitic capacitance is expected.

In the semiconductor device according to the present embodiment, the materials of the first sidewall 18 and the second sidewall 22 are selected to have appropriate Young's modulus and dielectric constants thereby optimizing the structure. Therefore, the nanowire transistor can be achieved in which the effect of improving the performance caused by the increase of the mobility due to strain application and the effect of improving the performance caused by the reduction of the parasitic capacitance are optimized.

According to the manufacturing method of the present embodiment, the first gate sidewall 18, formed immediately after the gate electrode 16 is formed, remains between the gate electrode 16 and the source/drain semiconductor layer 20 formed by the epitaxial growth until the end. Therefore, for example, this is different from such manufacturing method in which a silicon oxide film sidewall is buried in a groove between a gate electrode and a source/drain semiconductor layer, and no void is generated in the sidewall in the groove. Therefore, there is an advantage in that since the device structure can be stably manufactured, variation of device characteristics is suppressed.

Further, according to the manufacturing method of the present embodiment, for example, the silicon nitride film can be left only between the gate electrode 16 and the epitaxial silicon layer 20 in a self-aligning manner. Therefore, it is not necessary to strictly control the etching processing time of the silicon nitride film sidewalls with the hot phosphoric acid, and the manufacturing yield can be greatly improved.

When additional ion implantation and activation annealing are not performed after the gate sidewalls of the silicon oxide film, the number of steps of the manufacturing method of the present embodiment is the same as the number of steps of a generally-available method of manufacturing a nanowire transistor, which means that the manufacturing method of the present embodiment does not increase the process cost.

When the gate length is denoted with L, the width and the height of the nanowire is desirably (2/3)×L or less in order to obtain strong short-channel effect immunity. On the other hand, the width and the height of the silicon nanowire are desirably 3 nm or more in order to avoid excessive reduction of carrier mobility.

In the above explanation, there is only one narrow portion (nanowire) of the SOI layer. Alternatively, a plurality of silicon nanowires may be formed in parallel. By increasing the number of formed silicon nanowires, the amount of current in the transistor increases, and the operation speed improves.

In the embodiment, the n-type nanowire transistor has been explained as an example. The mobility improvement effect due to strain applied by the first sidewall is unique to the n-type nanowire transistor.

Even when the above embodiment is applied to the p-type nanowire transistor, the device structure can be stably manufactured, and there is an advantage in that the effect of suppressing variation of device characteristics can be obtained. In the case of the p-type nanowire transistor, the impurity of the source/drain region use p-type impurity such as boron (B) and indium (In).

The extension impurity region is formed by, for example, ion implantation with acceleration energy of about 1 to 2 keV of boron (B) or boron difluoride (BF₂). The source/drain impurity region is formed by, for example, ion implantation of boron (B), boron difluoride (BF₂), or indium (In).

### Second Embodiment

In the first embodiment, the SOI substrate is used. In contrast, a semiconductor device and a method of manufacturing the semiconductor device according to the present embodiment are different in that a bulk substrate is used. The second embodiment is basically the same as the first embodiment except for the difference in the semiconductor substrate, and therefore, the same contents are omitted from the description.

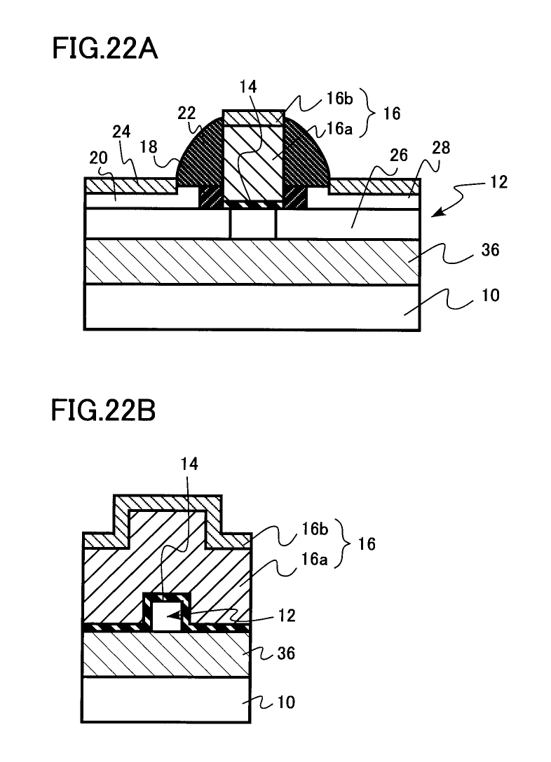

FIGS. 22A and 22B are cross-sectional schematic diagrams illustrating a semiconductor device according to the present embodiment. FIG. 22A is a schematic cross-sectional diagram in a gate lengthwise direction perpendicular to the substrate surface. FIG. 22B is a schematic cross-sectional diagram illustrating a gate electrode portion in the gate widthwise direction perpendicular to the substrate surface.

A bulk substrate is employed as a semiconductor substrate 10. Then, a narrow portion 12, or a so-called nanowire, is formed on the bulk substrate. In the present embodiment, a device isolation impurity region 36 is formed in the semiconductor substrate 10 under the narrow portion 12.

The device isolation impurity region 36 prevents a leak current from flowing from a source region to a drain region through a region under the nanowire in the bulk substrate. In a case of the n-type transistor, it is formed with p-type impurity. In a case of a p-type transistor, it is formed with n-type impurity. The impurity concentration is preferably 1×10¹⁷ cm⁻³ or more and 1×10¹⁹ cm⁻³ or less.

This introduction of the impurity can be achieved by performing ion implantation on the entire surface of the silicon substrate at a deep position before formation of the narrow portion 12, and performing side-direction diffusion process in the region under the narrow portion 12 by thermal processing. Alternatively, it can be achieved by performing ion implantation on a portion other than the narrow portion 12 after formation of the narrowed portion 12, and performing side-direction diffusion process in the region under the narrow portion 12 by thermal processing.

The present embodiment achieves the nanowire transistor and method of manufacturing the same that can achieve high performance even when made into a small size at a low cost without using expensive SOI substrate.

### Third Embodiment

The first embodiment relates to the nanowire transistor and method of manufacturing the same in which the gate insulating film and the gate electrode are formed on the top surface and the side surfaces of the narrow portion formed on the semiconductor substrate. In contrast, a semiconductor device and a method of manufacturing the semiconductor device according to the present embodiment are a so-called FinFET and method of manufacturing the same in which the gate insulating film and the gate electrode are not formed on the top surface of the narrow portion, and the gate insulating film and the gate electrode are formed only on the side surfaces of the narrow portion. The third embodiment is basically the same as the first embodiment except that the semiconductor device of the third embodiment is a FinFET, and therefore, the same contents are omitted from the description.

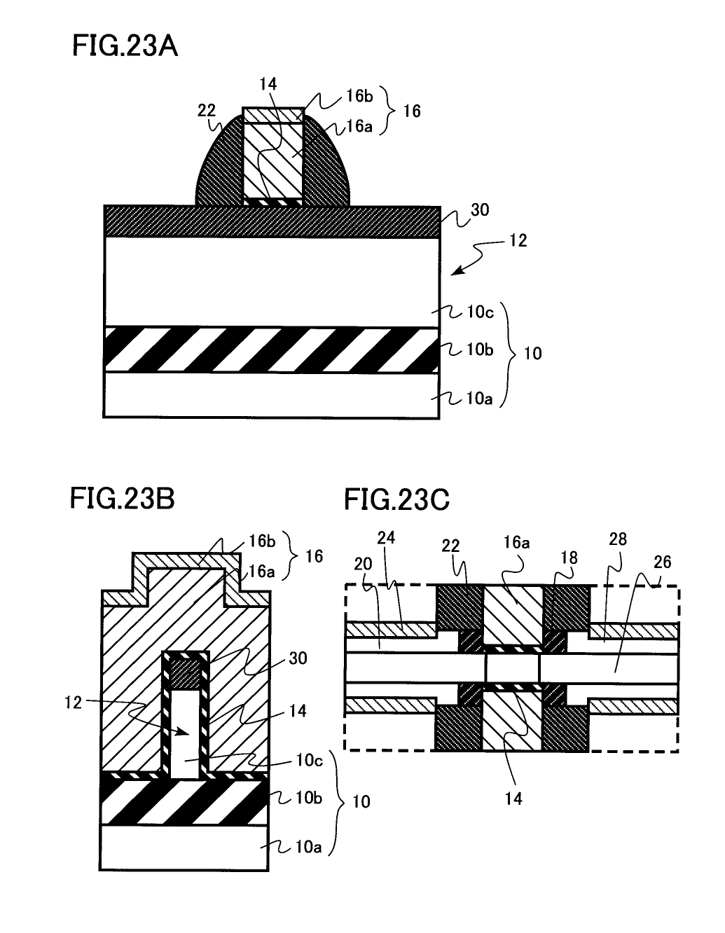

FIGS. 23A, 23B, and 23C are cross-sectional schematic diagrams illustrating a semiconductor device according to the present embodiment. FIG. 23A is a schematic cross-sectional diagram in a gate lengthwise direction perpendicular to the substrate surface. FIG. 23B is a schematic cross-sectional diagram illustrating a gate electrode portion in the gate widthwise direction perpendicular to the substrate surface. FIG. 23C is a schematic cross-sectional diagram illustrating a narrow portion in parallel to the substrate surface.

As shown in FIGS. 23A, 23B, and 23C, in the FinFET of the present embodiment, a gate insulating film 14 and a gate electrode 16 are formed only on the side surfaces of a narrow portion 12, and only the side surface portions of the narrow portion 12 function as a channel region. On the top surface of the narrow portion 12, a hard mask layer 30 is provided between the gate insulating film 14 and the gate electrode 16, and the top surface portion of the narrow portion 12 does not function as the channel region.

The Fin-type transistor of the present embodiment can be manufactured by not removing the hard mask layer 30 used for forming the narrow portion 12 before the gate insulating film 14 is formed.

In the present embodiment, like the first embodiment, the transistor characteristic can be improved. Therefore, the present embodiment achieves the FinFET and method of manufacturing the same that can achieve high performance even when made into a small size.

In the present embodiment, the SOI substrate is explained as an example of the semiconductor substrate.

Alternatively, like the second embodiment, the bulk substrate may also be used.

### Fourth Embodiment

A semiconductor device and a method of manufacturing the semiconductor device according to the present embodiment are a semiconductor device and a method of manufacturing the same in which an n-type nanowire transistor and a p-type nanowire transistor are provided on the same SOI substrate.

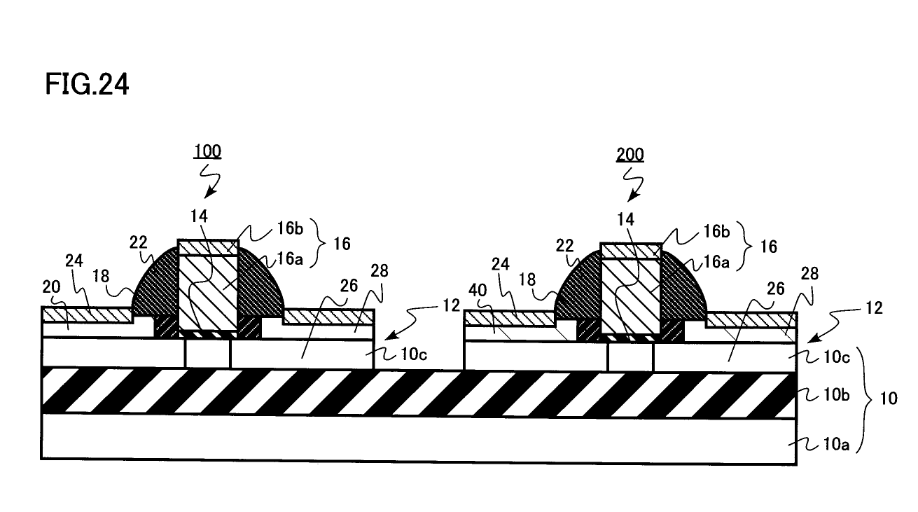

FIG. 24 is a cross-sectional schematic diagram illustrating a semiconductor device according to the present embodiment. FIG. 24 is a schematic cross-sectional diagram in a gate lengthwise direction perpendicular to the substrate surface.

An n-type nanowire transistor 100 and a p-type nanowire transistor 200 are formed on a semiconductor substrate 10, i.e., the same SOI substrate. The n-type nanowire transistor 100 and the p-type nanowire transistor 200 have the same structure as the first embodiment. Therefore, the same contents as the first embodiment are omitted from the description.

In this case, a source/drain semiconductor layer 20 of the n-type nanowire transistor 100 is silicon, and a source/drain semiconductor layer 40 of the p-type nanowire transistor 200 is silicon germanium.

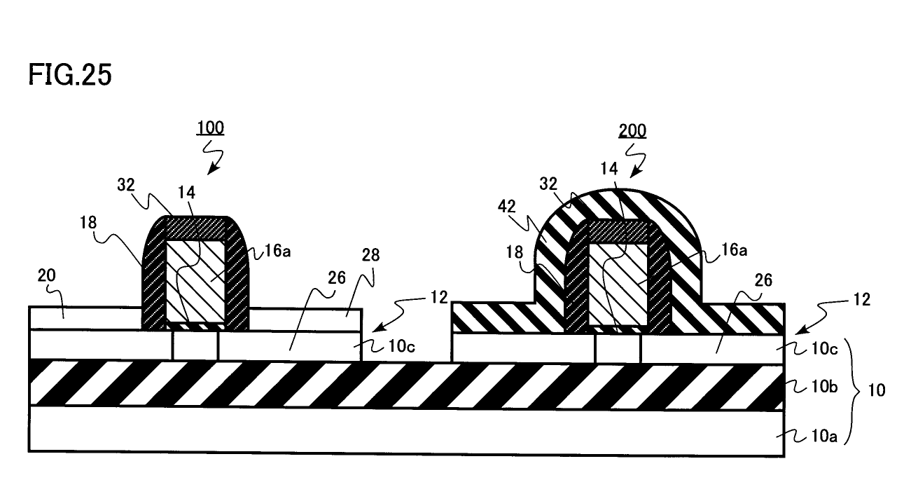

Hereinafter, a method of manufacturing the semiconductor device according to the present embodiment will be explained. FIGS. 25 to 28 are schematic diagram illustrating steps of the method of manufacturing the semiconductor device according to the present embodiment. FIGS. 25 to 28 are schematic cross-sectional diagrams in a gate lengthwise direction perpendicular to the substrate surface.

The present embodiment is the same as the first embodiment up to the following steps. First gate sidewalls 18 such as silicon nitride films are formed on both sides of the polysilicon layer 16a, i.e., a portion of the gate electrode 16, and thereafter ion implantation is performed to respectively form extension impurity regions 26 on the n-type nanowire transistor 100 and the p-type nanowire transistor 200, and annealing process is performed for activation and re-crystallization.

Subsequently, as shown in FIG. 25, for example, a protective insulating film 42 such as a silicon oxide film is formed on the p-type transistor 200 region, and thereafter, epitaxial silicon layers are grown on the exposed portions of the SOI layers 10c of the n-type transistor 100 region, so that the source/drain semiconductor layer 20 is formed. Subsequently, ion implantation of n-type impurity is performed in the source/drain semiconductor layer 20 of the n-type transistor 100, so that the source/drain region 28 is formed.

Subsequently, the protective insulating film 42 is removed from the p-type transistor 200 region. When the protective insulating film 42 is a silicon oxide film, for example, the protective insulating film 42 is removed by diluted hydrofluoric acid treatment.

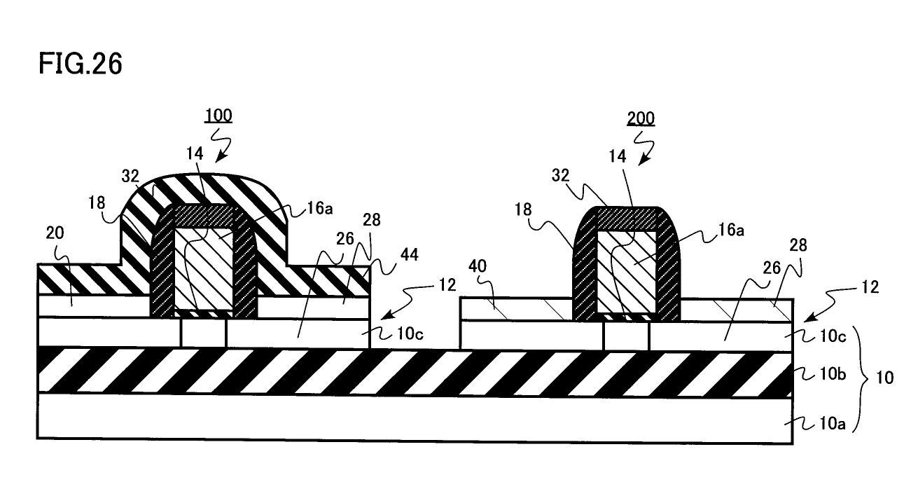

Subsequently, as shown in FIG. 26, a protective oxide film 44 such as a silicon oxide film is formed on the n-type transistor 100 region, and thereafter, epitaxial silicon germanium layers are grown on the exposed portions of the SOI layers 10c of the p-type transistor 200 region, so that source/drain semiconductor layer 40 is formed. Subsequently, ion implantation of p-type impurity is performed in the source/drain semiconductor layer 20 of the p-type transistor 200, so that the source/drain region 28 is formed.

Subsequently, after the protective insulating film 44 is removed from the n-type transistor 100 region, thermal processing, i.e., annealing, is performed to activate the impurity in the source/drain semiconductor layers 20, 40. Then, along with the activation, the thermal expansion of the first gate sidewall 18 is suppressed by the gate electrode polysilicon layer 16a and the epitaxial silicon layer 20 or the epitaxial silicon germanium layer 40 at both sides during the annealing, so that this increases the density of the region of the first gate sidewall 18 sandwiched by the polysilicon layer 16a and the epitaxial silicon layer 20 or the epitaxial silicon germanium layer 40, i.e., the region under the top surface of the epitaxial silicon layer 20 or the epitaxial silicon germanium layer 40.

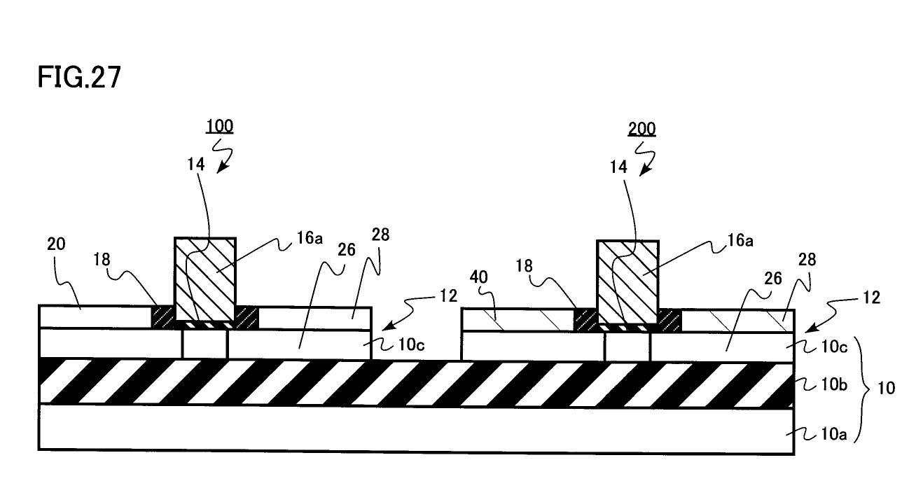

Subsequently, as shown in FIG. 27, for example, wet etching processing with hot phosphoric acid is performed, whereby this removes the hard mask nitride film 32 and the upper portion of the first gate sidewall 18 on the gate electrode polysilicon layer 16a, i.e., the region above the top surface of the epitaxial silicon layer 20 or the epitaxial silicon germanium layer 40.

The density of the region under the top surface of the epitaxial silicon layer or the epitaxial silicon germanium layer of the first gate sidewall 18 is increased during the above annealing process. Therefore, since the etching rate by the wet etching processing, e.g., the etching rate with the hot phosphoric acid, decreases, the region under the top surface of the epitaxial silicon layer or the epitaxial silicon germanium layer of the first gate sidewall 18 remains without being removed.

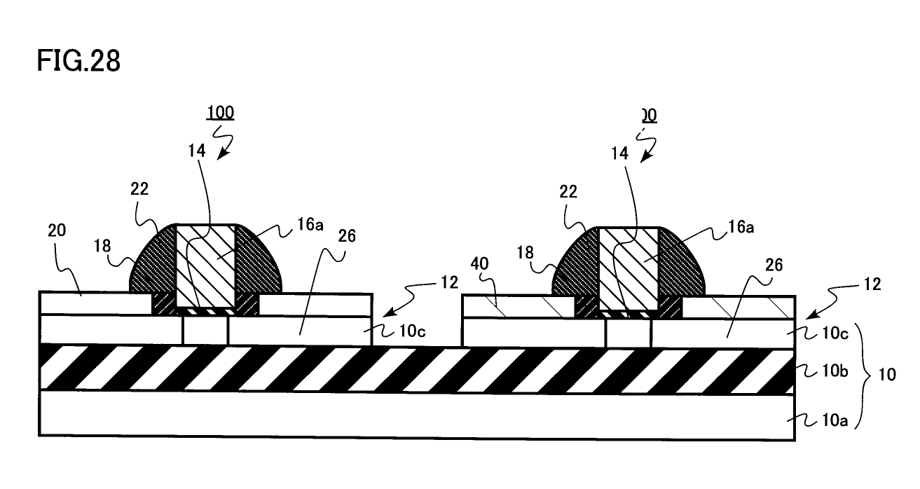

Subsequently, the silicon oxide film is deposited on the entire surface, and thereafter, as shown in FIG. 28, dry etching is performed to form second gate sidewalls 22 having a smaller Young's modulus and lower dielectric constant than the first gate sidewall 18 on the first gate sidewalls 18, the source/drain semiconductor layers 20 of the epitaxial silicon layers, and the source/drain semiconductor layers 40 of the silicon germanium layers so as to sandwich the polysilicon layers 16a of the gate electrodes. When the material of the first gate sidewall 18 is a silicon nitride film, the material of the second gate sidewall 22 is, for example, a silicon oxide film.

Thereafter, with the so-called salicide process, a metal silicide layer 16b is formed on the polysilicon layer 16a of the gate electrode, and metal silicide layers 24 are formed on the source/drain semiconductor layers 20, 40. As a result of the above process, the semiconductor device according to the present embodiment as shown in FIG. 24 is formed.

Like the first embodiment, in the semiconductor device according to the present embodiment, the first gate sidewall 18 having a large Young's modulus is formed between the polysilicon layer 16a of the gate electrode of the n-type transistor 100 and the source/drain semiconductor layer 20 formed by, for example, epitaxial growth. The first gate sidewall 18 having the large Young's modulus pressurizes the polysilicon layer 16a, so that the compressive strain occurs in a direction perpendicular to the side surface and the top surface of the silicon nanowire and the tensile strain occurs in the gate lengthwise direction of the channel region.

In the method of manufacturing the semiconductor device according to the present embodiment, the thermal expansion of the first gate sidewall 18 is suppressed by the gate electrode 16 and the source/drain semiconductor layer 20 at both sides during the annealing, i.e., thermal processing. As a result, the first gate sidewall 18 pressurizes the polysilicon layer 16a, so that the compressive strain occurs in a direction perpendicular to the side surface and the top surface of the silicon nanowire and the tensile strain occurs in the gate lengthwise direction of the channel region.

As described above, in the channel region of the nanowire transistor, a large tensile strain occurs in the gate lengthwise direction of the nanowire transistor. When the nanowire transistor is an n-type transistor, the mobility of the nanowire transistor improves due to such tensile strain in the gate lengthwise direction. Therefore, the mobility of the n-type transistor 100 increases, and as a result, ON current performance improves.

On the other hand, the mobility in the p-type transistor 200 is degraded by the tensile strain in the gate lengthwise direction channel-induced by the first gate sidewall 18 having a high Young's modulus. However, compressive strain in the gate lengthwise direction is induced to the channel region from the epitaxial silicon germanium layer having a larger lattice constant than the silicon, i.e., the source/drain semiconductor layer 40 of the p-type transistor 200. Therefore, as a whole, strain in the gate lengthwise direction is cancelled, or if the amount of compressive strain given from the silicon germanium layer is sufficiently large, compressive strain occurs in the gate lengthwise direction as a whole, which improves the mobility of the p-type nanowire transistor.

Therefore, in the present embodiment, both the mobility of the n-type nanowire transistor and the mobility of the p-type nanowire transistor can be improved.

Further, like the first embodiment, the present embodiment is also configured such that the first gate sidewalls 18 of, for example, the silicon nitride film, having a relatively high dielectric constant are formed only in the lower portion at both sides of the gate electrode 16, and the second gate sidewalls 22 of, for example, the silicon oxide film, having a relatively low dielectric constant are formed only in the upper portion at both sides of the gate electrode 16. Therefore, as compared with a case where gate sidewalls of silicon nitride films having high dielectric constant are formed on the entire surfaces at both sides of the gate electrode 16, the increase of the parasitic capacitance is suppressed.

Like the first embodiment, the present embodiment is configured such that the first gate sidewall 18, formed immediately after the gate electrode 16 is formed, remains between the gate electrode 16 and the epitaxial silicon layer 20/the silicon germanium layer 40 until the end. Therefore, unlike process in which a sidewall film such as a silicon oxide film is buried in a groove between a gate electrode and an epitaxial silicon layer, no void is generated in the sidewall in the groove. Therefore, there is an advantage in that since the device structure can be stably manufactured, variation of device characteristics is suppressed.

Like the first embodiment, in the present embodiment, the first gate sidewall 18 can be left in a self-aligning manner only between the gate electrode 16 and the source/drain semiconductor layer 20 formed by epitaxial growth. Therefore, it is not necessary to strictly control the wet etching processing time with the hot phosphoric acid and the like, and the manufacturing yield can be greatly improved.

Further, like the first embodiment, in the present embodiment, when additional ion implantation and activation annealing are not performed after the second gate sidewall 22 is formed, the number of steps of the manufacturing method of the present embodiment is the same as the number of steps of a conventional method of manufacturing a nanowire transistor in which an epitaxial silicon film is formed on a source/drain region of an n-type transistor and an epitaxial silicon germanium film is formed on a source/drain region of a p-type transistor, which means that the manufacturing method of the present embodiment does not increase the process cost.

As described above, the present embodiment can achieve the semiconductor device having the n-type nanowire transistor and the p-type nanowire transistor that can achieve high performance even when made into a small size, and the method of manufacturing the same.

### Fifth Embodiment

The first embodiment is the nanowire transistor formed on the SOI substrate and method of manufacturing the same. In contrast, a semiconductor device and a method of manufacturing the semiconductor device according to the present embodiment relate to a planar transistor formed on a bulk substrate and method of manufacturing the same. The structure around the gate sidewall and the manufacturing method therefor are basically the same as those of the first embodiment. Therefore, the same contents are omitted from the description.

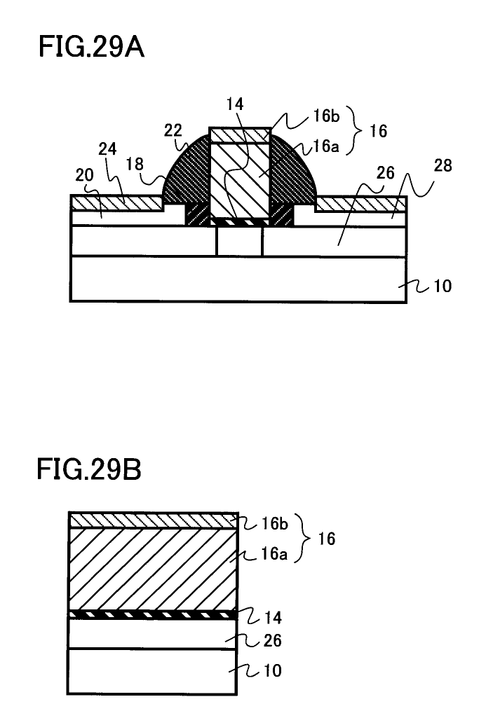

FIGS. 29A and 29B are cross-sectional schematic diagrams illustrating a semiconductor device according to the present embodiment. FIG. 29A is a schematic cross-sectional diagram in a gate lengthwise direction perpendicular to the substrate surface. FIG. 29B is a schematic cross-sectional diagram illustrating a gate electrode portion in the gate widthwise direction perpendicular to the substrate surface.

The planar transistor includes a gate insulating film 14 formed on the semiconductor substrate 10 of (100) plane silicon, a gate electrode 16 formed on the gate insulating film 14, first gate sidewalls 18 formed at both sides of the gate electrode 16, extension impurity regions 26 formed to sandwich a channel region serving as a region under the gate electrode 16 in the semiconductor substrate 10, a source/drain semiconductor layer 20 formed on the extension impurity region 26 to sandwich the first gate sidewalls 18 with the gate electrode 16, and second gate sidewalls formed on the first gate sidewall 18 and the source/drain semiconductor layer 20 at both sides of the gate electrode 16, wherein the boundary of the second gate sidewall with the first gate sidewall is terminated at the side surface of the gate electrode, and the second gate sidewall has a smaller Young's modulus and a lower dielectric constant than the first gate sidewall 18.

Like the first embodiment, desirably the first boundary surface between the first gate sidewall 18 and the second gate sidewall 22 is at the side of the semiconductor substrate 10 with respect to the second boundary surface between the source/drain semiconductor layer 20 and the second gate sidewall 22, and the distance between the first boundary surface and the second boundary surface is 10 nm or less in a normal line direction of the boundary surface between the gate insulating film 14 and the semiconductor substrate 10. In other words, the top surface of the first gate sidewall 18 is desirably located at a position within 10 nm under the top surface of the source/drain semiconductor layer 20.

The first gate sidewall 18 is, for example, a silicon nitride film, and the second gate sidewall 22 is, for example, a silicon oxide film. The source/drain semiconductor layer 20 is, for example, an epitaxial silicon layer having a thickness of 10 to 50 nm.

Metal silicide layers 24 are formed on the source/drain semiconductor layer 20 at both sides of the second gate sidewall 22.

In this structure, the cross-sectional area of the semiconductor of the source/drain region is increased by the source/drain semiconductor layer 20, and therefore, the parasitic resistance is greatly reduced, and the ON current of the transistor significantly improves.

The manufacturing method of the present embodiment is substantially the same as the manufacturing method of the first embodiment except the step of narrowing the SOI layer in which the channel region is formed. However, in order to operate the planar transistor with the gate length is 50 nm or less, it is necessary to introduce p-type impurity (for n-type transistor) and n-type impurity (for p-type transistor) into the semiconductor substrate 10 with a concentration of 1×10¹⁷ cm⁻³ to 1×10¹⁹ cm⁻³. This introduction of the impurity can be achieved by performing well ion implantation or channel ion implantation on the entire surface of the semiconductor substrate 10 of silicon before forming the gate insulating film 14 or by performing ion implantation, i.e., so-called halo ion implantation after the gate electrode 16 and the gate sidewalls are formed.

Like the semiconductor device according to the first embodiment, the first gate sidewall 18 having a large Young's modulus is formed between the polysilicon layer 16a of the gate electrode of the n-type transistor and the source/drain semiconductor layer 20 formed by, for example, epitaxial growth. The first gate sidewall 18 having the large Young's modulus pressurizes the polysilicon layer 16a, so that the compressive strain occurs in a direction perpendicular to the top surface of the channel region and the tensile strain occurs in the gate lengthwise direction of the channel region.

In the method of manufacturing the semiconductor device according to the present embodiment, the thermal expansion of the first gate sidewall 18 is suppressed by the gate electrode 16 and the source/drain semiconductor layer 20 at both sides during the annealing, i.e., thermal processing. Accordingly, the first gate sidewall 18 pressurizes the polysilicon layer 16a, so that the compressive strain occurs in a direction perpendicular to the top surface of the channel region and the tensile strain occurs in the gate lengthwise direction of the channel region.

As described above, in the channel region of the planar transistor, large tensile strain occurs in the gate lengthwise direction. In a case of the n-type transistor, the mobility of the planar transistor improves due to the tensile strain in the gate lengthwise direction as described above. Therefore, the mobility of the n-type transistor increases, and as a result, ON current performance improves.

Like the first embodiment, the present embodiment is also configured such that the first gate sidewalls 18 having high dielectric constant are formed in the lower portions at both sides of the gate electrode 16, i.e., the regions below the top surface of the source/drain semiconductor layer 20, and the second gate sidewalls 22 having low dielectric constant are formed in the upper portions at both sides of the gate electrode 16. Therefore, as compared with a case where gate sidewalls having high dielectric constant such as silicon nitride films are formed on the entire surfaces at both sides of the gate electrode 16, the increase of the parasitic capacitance is suppressed.

Further, according to the manufacturing method of the present embodiment, the first gate sidewall 18, formed immediately after the gate electrode 16 is formed, remains between the gate electrode 16 and the source/drain semiconductor layer 20 formed by the epitaxial growth until the end. Therefore, for example, this is different from such manufacturing method in which a silicon oxide film sidewall is buried in a groove between a gate electrode and a source/drain semiconductor layer, and no void is generated in the sidewall in the groove. Therefore, there is an advantage in that since the device structure can be stably manufactured, variation of device characteristics is suppressed.

Further, according to the manufacturing method of the present embodiment, for example, the silicon nitride film can be left only between the gate electrode and the epitaxial silicon layer in a self-aligning manner. Therefore, it is not necessary to strictly control the etching processing time of the silicon nitride film sidewalls with the hot phosphoric acid, and the manufacturing yield can be greatly improved.

In the manufacturing method of the present embodiment, for example, when additional ion implantation and activation annealing are not performed after the second gate sidewalls of the silicon oxide films are formed, the number of steps of the manufacturing method of the present embodiment is the same as the number of steps of a conventional method of manufacturing a planar transistor in which an epitaxial silicon film is formed on a source/drain region, which means that the manufacturing method of the present embodiment does not increase the process cost.

As described above, the present embodiment can achieve the planar transistor and method of manufacturing the same that can achieve high performance even when made into a small size.

### Sixth Embodiment

In a method of manufacturing a semiconductor device according to the present embodiment, a first sacrificial semiconductor layer, a first semiconductor layer, a second sacrificial semiconductor layer, and a second semiconductor layer are formed on a semiconductor substrate in order. Then, the first sacrificial semiconductor layer, the first semiconductor layer, the second sacrificial semiconductor layer, and the second semiconductor layer are patterned to form a narrow portion. Then, a tunnel insulating film is formed at least on side surfaces of a narrow portion. Then, a charge storage film of a silicon nitride film for storing charges is formed on the tunnel insulating film. Then, a block insulating film is formed on the charge storage film. Then, a gate electrode film is formed on the block insulating film. Then, the tunnel insulating film, the charge storage film, the block insulating film, and the gate electrode film are patterned to make a gate electrode structure. Then, the first sacrificial semiconductor layer and the second sacrificial semiconductor layer are selectively removed, whereby a first hollow is formed between the second semiconductor layer and the first semiconductor layer of the narrow portion. Then, the thermal processing is performed to remove a portion of the silicon nitride film by wet etching, whereby a second hollow is formed in the charge storage film. Further, an insulating film that is different from the silicon nitride film is deposited to fill the first hollow and the second hollow, and the insulating film is patterned to form gate sidewalls at both sides of the gate electrode structure.

The present embodiment relates to a method of manufacturing a semiconductor storage device having a MONOS (Metal-Oxide-Nitride-Oxide-Semiconductor) memory using a nanowire as a channel region.

In this specification, the “charge storage film” is a film having a function of actively storing charges as memory cell information. The “tunnel insulating film” is a film functioning as an electrons/holes moving path between the channel region and the charge storage film due to tunneling phenomenon during writing/erasing operation of a memory cell. In addition, the “tunnel insulating film” also has a function of suppressing electrons/holes movement between the channel region and the charge storage film due to barrier height thereof during reading operation and waiting state. The “block insulating film” is a so-called inter-electrode insulating film having a function of blocking flow of electrons/holes between the charge storage film and the gate electrode.

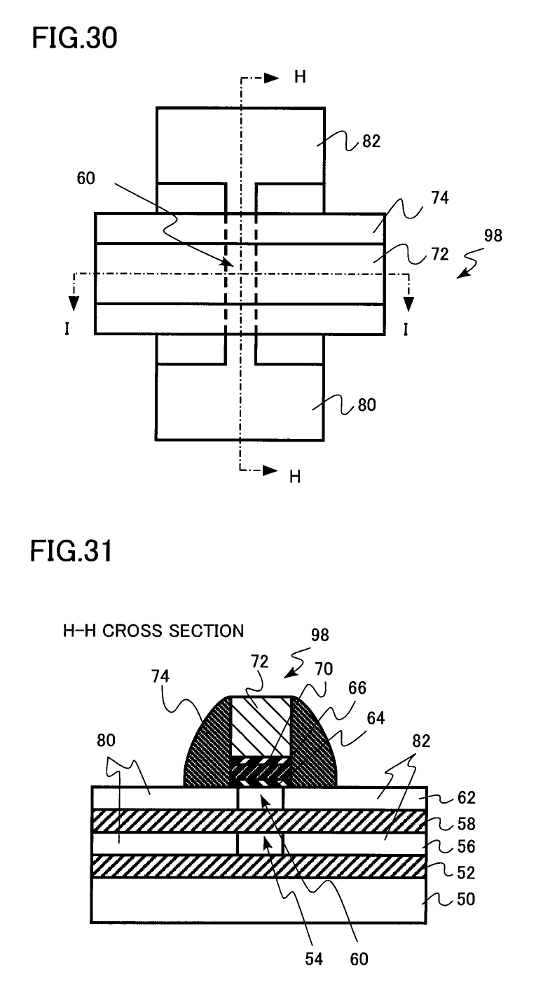

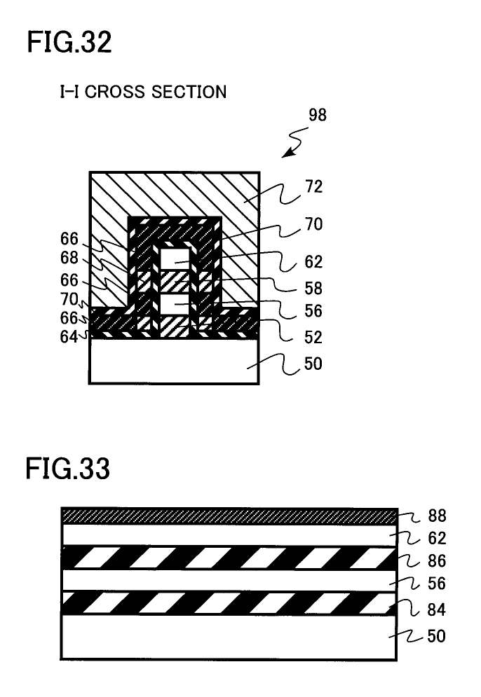

FIG. 30 is a top surface schematic diagram illustrating a semiconductor storage device manufactured according to the method of manufacturing the semiconductor device of the present embodiment. FIG. 31 is a cross-sectional schematic diagram illustrating a cross section taken along H-H of FIG. 30, i.e., a cross section in a gate lengthwise direction perpendicular to the substrate. FIG. 32 is a cross-sectional schematic diagram illustrating a cross section taken along I-I of FIG. 30, i.e., a cross section in a gate lengthwise direction of the gate electrode portion perpendicular to the substrate.

The semiconductor storage device includes a first insulating body layer 52 having a narrow portion formed on a semiconductor substrate 50, for example, silicon substrate, and a first semiconductor layer 56 made of, for example, silicon, having a first nanowire 54 serving as a narrow portion formed on the top surface of the first insulating body layer 52. In addition, the semiconductor storage device further includes a second insulating body layer 58 having a narrow portion formed on the top surface of the first semiconductor layer 56 and a second semiconductor layer 62 made of, for example, silicon, having a second nanowire 60 serving as a narrow portion formed on the top surface of the second insulating body layer 58.

In addition, the semiconductor storage device further includes tunnel insulating films 64 formed at least on side surfaces of the first nanowire 54 and the second nanowire 60 and a charge storage film 66 of a silicon nitride film formed on the tunnel insulating film 64. In addition, the semiconductor storage device further includes an inter-charge-storage-film insulating body layer 68 made of an insulating film different from the silicon nitride film formed on the charge storage film 66, a block insulating film 70 formed on the charge storage film 66 and the inter-charge-storage-film insulating body layer 68, and a gate electrode film 72 formed on the block insulating film 70.

A gate electrode structure 98 is formed by the tunnel insulating film 64, the silicon nitride film serving as the charge storage film 66, the block insulating film 70, and the gate electrode film 72.

Gate sidewalls 74 formed to sandwich the gate electrode structure 98 are provided. Further, source regions 80 and drain regions 82 formed at both sides of the gate sidewall 74 are provided in the first semiconductor layer 56 and the second semiconductor layer 62.

The first insulating body layer 52 and the second insulating body layer 58 are, for example, silicon oxide films. The first semiconductor layer 56 and the second semiconductor layer 62 are, for example, silicon. Therefore, in this case, both of the first nanowire 54 and the second nanowire 60 are silicon nanowires. Hereinafter, they are referred to as the first silicon nanowire 54 and the second silicon nanowire 60, respectively.

The tunnel insulating film 64 is, for example, a silicon oxide film. The inter-charge-storage-film insulating body layer 68 is formed of, for example, a silicon oxide film. The gate electrode film 72 is, for example, a polysilicon film.

The drain region 82 in the first semiconductor layer 56 is electrically insulated from the drain region 82 in the second semiconductor layer 62. Then, each of the transistor using the first silicon nanowire 54 as the channel and the transistor using the second silicon nanowire 60 as the channel operates as an independent MONOS cell transistor.

In other words, each of the transistor using the first silicon nanowire 54 as the channel region and the MONOS cell transistor using the second silicon nanowire 60 as the channel region plays a role of storing data of either “0” or “1”.

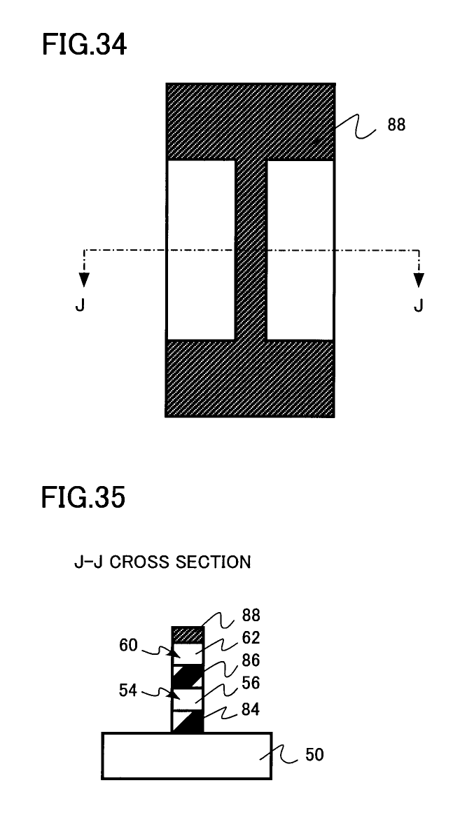

Hereinafter, a method of manufacturing the semiconductor device according to the present embodiment will be explained. FIGS. 33 to 39 are schematic diagrams illustrating steps of a method of manufacturing the semiconductor device according to the present embodiment. FIGS. 33, 35, 36, 38, and 39 are cross-sectional schematic diagrams. FIGS. 34 and 37 are top surface schematic diagrams.

In the explanation below, for example, the following case is assumed. The substrate is a silicon substrate, the first and second semiconductor layers are silicon, and the first and second sacrificial semiconductor layers are silicon germanium.

As shown in FIG. 33, the following structure is formed on the silicon substrate 50. The structure includes a first silicon germanium layer, i.e., the first sacrificial semiconductor layer 84, a first silicon layer, i.e., the first semiconductor layer 56, a second silicon germanium layer, i.e., the second sacrificial semiconductor layer 86, a second silicon layer, i.e., the second semiconductor layer 62, and the hard mask layer 88. The thicknesses of the first and second silicon germanium layers 84, 86 and the first and second silicon layers 56, 62 are about 3 to 40 nm.

Subsequently, as shown in FIG. 34 showing the top surface schematic diagram and FIG. 35 taken along cross section J-J of FIG. 34, the hard mask layer 88 is patterned, and thereafter using the hard mask layer 88 as a mask, the first silicon germanium layer 84, the first silicon layer 56, the second silicon germanium layer 86, and the second silicon layer 62 are etched. As a result of this etching, some portions of the first silicon germanium layer 84, the first silicon layer 56, the second silicon germanium layer 86, and the second silicon layer 62 are narrowed in the gate widthwise direction. In other words, some portions of these layers are patterned into plate-like shapes, whereby the narrow portion is formed. The width of each layer made into the plate-like shape is about 3 to 40 nm.

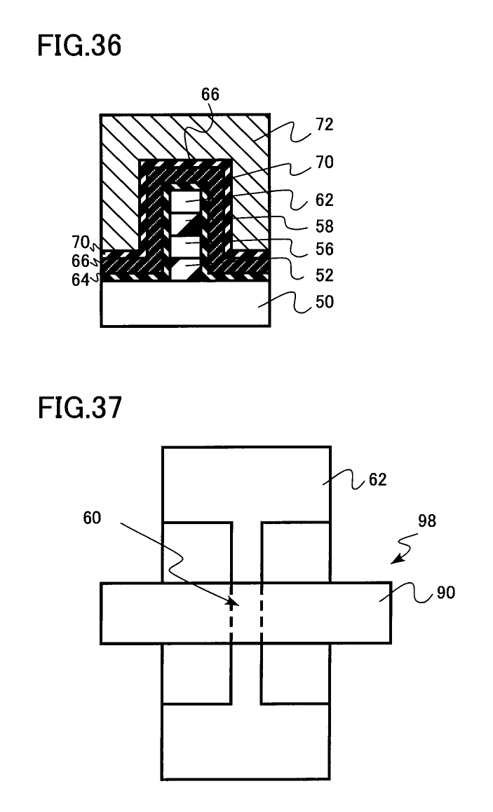

Subsequently, as shown in FIG. 36 showing the cross-sectional schematic diagram in the gate widthwise direction, the hard mask layer 88 is removed, and thereafter, the tunnel insulating film 64, the silicon nitride film serving as the charge storage film 66, the block insulating film 70, and the gate electrode film 72 are formed on the narrowed second silicon layer 62, i.e., the top surface and the side surfaces of the second silicon nanowire 60 and the side surfaces of the narrowed second silicon germanium layer 86, and on the narrowed first silicon layer 56, i.e., the side surfaces of the first silicon nanowire and the side surfaces of the narrowed first silicon germanium layer 84.

The tunnel insulating film 64 and the block insulating film 70 may be a silicon oxide film, a silicon oxynitride film, a silicon nitride film, a stacked film including a silicon oxide film and a silicon nitride film, a high dielectric constant insulating film, or a stacked film including a silicon oxide film and a high dielectric constant film. The gate electrode film 72 may be, for example, a metal-semiconductor compound single film such as a polysilicon single film and metal silicide, a metal film such as TiN, W, and TaC, a stacked film including a metal-semiconductor compound film other than the metal silicide and a semiconductor such as a polysilicon film, or a stacked film including a metal film and a semiconductor such as a polysilicon film.

Subsequently, a hard mask nitride film 90 is formed on the gate electrode film 72, and the hard mask nitride film 90 is patterned. Thereafter, using the hard mask nitride film 90 as a mask, the tunnel insulating film 64, the charge storage film 66, the block insulating film 70, and the gate electrode film 72 are patterned. Then, as shown in FIG. 37, the gate electrode structure 98 is formed in such a manner that the tunnel insulating film 64, the charge storage film 66, the block insulating film 70, and the gate electrode film 72 are left only on the portion on the silicon nanowire.

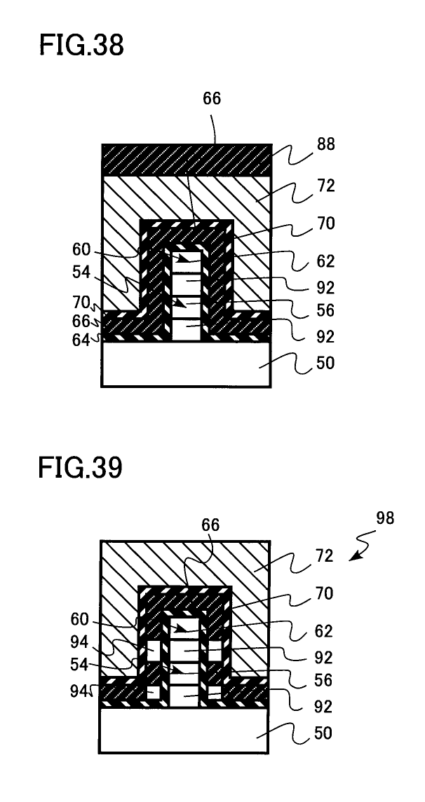

Subsequently, as shown in FIG. 38 showing the cross-sectional schematic diagram in the gate widthwise direction, the silicon germanium is etched to be selectively removed, so that the first silicon germanium layer 84 and the second silicon germanium layer 86 are removed. Selective etching of the silicon germanium can be achieved by, for example, hydrochloric acid solution. A first hollow 92 is formed in the region from which the first silicon germanium layer 84 and the second silicon germanium layer 86 are removed.

Subsequently, thermal processing, i.e., annealing, is performed to increase the density of the silicon nitride film serving as the charge storage film 66 sandwiched between the first silicon nanowire 54 and the gate electrode film 72 and increase the density of the charge storage film 66 between the second silicon nanowire 60 and the gate electrode film 72.

Subsequently, as shown in FIG. 39 showing the cross-sectional schematic diagram in the gate widthwise direction, wet processing with hot phosphoric acid is performed to remove the hard mask nitride film 88 and the regions in the charge storage film 66 that are not sandwiched between the first silicon nanowire 54 and the gate electrode 98 or between the second silicon nanowire 60 and the gate electrode 98, so that a second hollow 94 is formed. Since the annealing process has increased the density in the regions in the silicon nitride film serving as the charge storage film 66 that are sandwiched between the first silicon nanowire 54 and the gate electrode 98 or between the second silicon nanowire 60 and the gate electrode 98, such regions are left without being removed even when process with hot phosphoric acid is performed.

Subsequently, for example, an insulating film 96 different from the silicon nitride film, such as a silicon oxide film, is deposited on the entire surface, so as to fill the first hollow 92 and the second hollow 94 generated in the silicon germanium layer removing step and the silicon nitride film removing step. The insulating film 96 is a substance having a higher degree of insulation than the charge storage film 66.

Then, the gate sidewalls 74 are formed to sandwich the gate electrode structure 98 by performing dry etching process (FIG. 31). Further, the first insulating body layer 52 and the second insulating body layer 58 are formed.

After the gate sidewalls 74 are formed, ion implantation is performed to form the source regions 80 and the drain regions 82 so as to sandwich the gate sidewall 74 in the first silicon layer 56 and the second silicon layer 62 (FIG. 31).

Thereafter, ordinary or known MONOS memory manufacturing steps are performed to complete the structure as shown in FIGS. 30 to 32.

According to the manufacturing method of the present embodiment, the charge storage film 66 sandwiched between the first silicon nanowire 54 and the gate electrode film 72, i.e., the region in which storage charges of the transistor having the first silicon nanowire 54 as the channel are held, is physically separated and insulated from the charge storage film 66 sandwiched between the second silicon nanowire 60 and the gate electrode 74, i.e., the region in which storage charges of the transistor having the second silicon nanowire 60 as the channel are held. Therefore, the storage charges do not flow out from one of the cell transistors to the other of the cell transistors, and the storage data in each cell transistor do not interfere with each other. Therefore, high memory performance can be achieved even when made into a small size.

In the above explanation, the stacked silicon nanowire includes two layers, i.e., the first silicon nanowire 54 and the second silicon nanowire 60, but the number of silicon nanowires can be increased so that the stacked silicon nanowire includes the third and fourth layers. When the number of stacked layers in the silicon nanowire increases, the number of stored bits, i.e., the capacity of the memory, increases.

In the above explanation, there is only one silicon nanowire formed in the same plane in parallel to the silicon substrate 50. Alternatively, a plurality of silicon nanowires, i.e., narrow portions of silicon layers, may be formed in parallel within the same plane. When the number of formed silicon nanowires increases, the number of stored bits also increases.

As described above, the present embodiment achieves the method of manufacturing the semiconductor storage device having the MONOS memory using the nanowire as the channel region capable of achieving high performance even when made into a small size.

While certain embodiments have been described, these embodiments have been presented by way of example only, and are not intended to limit the scope of the inventions. Indeed, the semiconductor device and the method of manufacturing the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

In the above explanation about the embodiments, for example, the substrate is the silicon substrate, the first and second semiconductor layers are silicon, and the first and second sacrificial semiconductor layers are silicon germanium. Alternatively, other semiconductor materials may be used.

What is claimed is:

1. A semiconductor device comprising:
a semiconductor substrate;
a gate insulating film formed on the semiconductor substrate;
a gate electrode formed on the gate insulating film;
first gate sidewalls formed at both sides of the gate electrode;
a source/drain semiconductor layer formed on the semiconductor substrate, the first gate sidewalls being interposed between the source/drain semiconductor layer and the gate electrode; and
second gate sidewalls formed at both sides of the gate electrode and formed on the first gate sidewalls and the source/drain semiconductor layer, wherein a boundary of each of the second gate sidewalls with each of the first gate sidewalls is terminated at a side surface of the gate electrode, and each of the second gate sidewalls has a smaller Young's modulus and a lower dielectric constant than each of the first gate sidewalls.

2. The device according to claim 1, wherein the semiconductor substrate has a substrate semiconductor layer including a narrow portion, and the gate insulating film is formed at least on side surfaces of the narrow portion.

3. The device according to claim 2, wherein the semiconductor substrate is an SOI (Silicon On Insulator) substrate, and the substrate semiconductor layer is formed of the SOI layer.

4. The device according to claim 1, wherein each of the first gate sidewalls is a silicon nitride film, and each of the second gate sidewalls is a silicon oxide film.

5. The device according to claim 1, wherein a first boundary surface between each of the first gate sidewalls and each of the second gate sidewalls is at a side of the semiconductor substrate with respect to a second boundary surface between the source/drain semiconductor layer and each of the second gate sidewalls, and a distance between the first boundary surface and the second boundary surface is 10 nm or less in a normal line direction of a boundary surface between the gate insulating film and the semiconductor substrate.

6. The device according to claim 1, wherein the gate electrode is a polysilicon film, a stacked film including a metal semiconductor compound film and a polysilicon film, a stacked film including a metal film and a polysilicon film, or a metal film.

7. The device according to claim 1, wherein the source/drain semiconductor layer is silicon, silicon germanium, or silicon carbon.

8. The device according to claim 2, wherein a plurality of narrow portions is provided in parallel.

9. A method of manufacturing a semiconductor device, comprising:
forming a gate insulating film on a semiconductor substrate;
forming a gate electrode on the gate insulating film;
forming first gate sidewalls at both sides of the gate electrode;
forming source/drain semiconductor layers on the semiconductor substrate at both sides of the gate electrode by selective growth;
performing thermal processing;
performing wet etching to remove portions of the first gate sidewalls; and
forming second gate sidewalls on the first gate sidewalls and the source/drain semiconductor layer at both sides of the gate electrode, wherein each of the second gate sidewalls has a smaller Young's modulus and a lower dielectric constant than each of the first gate sidewalls.

10. The method according to claim 9, wherein a narrow portion is formed in a substrate semiconductor layer at an upper portion of the semiconductor substrate, and the gate insulating film is formed at least on side surfaces of the narrow portion.

11. The method according to claim 9, wherein each of the first gate sidewalls is a silicon nitride film, and the wet etching is hot phosphoric acid processing.

12. The method according to claim 10, wherein a plurality of narrow portions is formed in parallel.

13. A method of manufacturing a semiconductor device, comprising:
forming, on a semiconductor substrate, a first sacrificial semiconductor layer, a first semiconductor layer, a second sacrificial semiconductor layer, and a second semiconductor layer in order;
patterning the first sacrificial semiconductor layer, the first semiconductor layer, the second sacrificial semiconductor layer, and the second semiconductor layer to form a narrow portion;
forming a tunnel insulating film at least on side surfaces of the narrow portion;
forming a charge storage film of a silicon nitride film on the tunnel insulating film;
forming a block insulating film on the charge storage film;
forming a gate electrode film on the block insulating film;
patterning the tunnel insulating film, the charge storage film, the block insulating film, and the gate electrode film to form a gate electrode structure;
forming a first hollow between the first semiconductor layer and the second semiconductor layer in the narrow portion by selectively removing the first sacrificial semiconductor layer and the second sacrificial semiconductor layer;
performing thermal processing;
forming a second hollow in the charge storage film by removing a portion of the silicon nitride film by wet etching;
depositing an insulating film different from the silicon nitride film filling the first hollow and the second hollow; and
patterning the insulating film to form gate sidewalls at both sides of the gate electrode structure.

14. The method according to claim 13, wherein a plurality of narrow portions is formed in parallel.

15. The method according to claim 13, wherein the first and second sacrificial semiconductor layers are silicon germanium, and the first and second semiconductor layers are silicon.
